(19) United States
(12) Patent Application Publication
(10) Pub. No.: US 2015/0206981 A1
(43) Pub. Date: Jul. 23, 2015

(54) SEMICONDUCTOR DEVICE, DISPLAY DEVICE, AND MANUFACTURING METHOD OF SEMICONDUCTOR DEVICE

(71) Applicant: Sony Corporation, Tokyo (JP)

(72) Inventor: Jun Komachi, Kanagawa (JP)

(21) Appl. No.: 14/553,454

(22) Filed: Nov. 25, 2014

(30) Foreign Application Priority Data
Jan. 17, 2014 (JP) 2014-006741

(51) Int. Cl. H01L 29/786; H01L 27/12; H01L 29/66

(52) U.S. Cl. CPC H01L 29/78618; H01L 29/7869; H01L 29/66969; H01L 27/1225

(57) ABSTRACT

There is provided a semiconductor device including a first region which, in an oxide semiconductor layer, has a higher carrier concentration than a channel region immediately below a gate electrode formed over the oxide semiconductor layer and is formed at least in a partial region other than the channel region, and a second region which, in the oxide semiconductor layer, has a higher carrier concentration than the first region and is formed farther from the channel region than the first region. The first region is formed through a first reduction reaction by stacking a first reduction reaction film over the oxide semiconductor layer and reducing the oxide semiconductor layer by the first reduction reaction film. The second region is formed through a second reduction reaction by stacking a second reduction reaction film over the oxide semiconductor layer and reducing the oxide semiconductor layer by the second reduction reaction film.

### CROSS REFERENCE TO RELATED APPLICATIONS

This application claims the benefit of Japanese Priority Patent Application JP 2014-006741 filed Jan. 17, 2014, the entire contents of which are incorporated herein by reference.

### BACKGROUND

The present disclosure relates to a semiconductor device, a display device, and a manufacturing method of a semiconductor device.

In recent years, as a next-generation integrated circuit (IC) or a transistor mounted in electronic apparatuses such as display devices, for example, a field effect transistor (which may also be referred to hereinafter simply as a “transistor”) that is formed on an oxide semiconductor film has been noticed.

For example, “A Novel Self-Aligned Top-Gate Oxide TFT for AM-OLED Displays” written by Narihiro Morosawa, Yoshihiko Ohshima, Mitsuo Morooka, Toshiaki Arai, and Tatsuya Sasaoka in SID 11 DIGEST in 2011 proposes on pages 479 to 482 a technology in which, in a transistor formed on an oxide semiconductor film, a gate insulation film and a gate electrode are formed on the oxide semiconductor film, a metal thin film made of aluminum (Al) or the like is stacked and appropriate heat treatment is performed thereon to cause an oxidation-reduction reaction between the oxide semiconductor film and the metal thin film, thereby adjusting a carrier concentration of regions corresponding to a source region and a drain region in the oxide semiconductor film. In addition, in order to alleviate concentration of an electric field on edges of a drain region and a source region abutting a gate electrode in a transistor that is formed on an oxide semiconductor film, JP 2013-48217A proposes a technology for causing a phased difference in carrier concentrations inside the source region and the drain region using both an oxidation-reduction reaction between the oxide semiconductor film and a metal thin film as described above and injection of impurities through ion implantation into the oxide semiconductor film.

### SUMMARY

Here, in the technology disclosed in JP 2013-48217A, a sidewall insulation film (a so-called sidewall) is formed in a gate electrode, and impurities are injected from the sidewall, and thereby a difference in carrier concentrations inside the source region and the drain region is made in stages. In this method, however, it is necessary to perform ion implantation with energy high enough to realize penetration of the sidewall, which makes the process more difficult. In addition, controlling a carrier concentration inside a region immediately below the sidewall with high accuracy is considered difficult. As described above, there is a possibility in the technology disclosed in JP 2013-48217A of difficulty in controlling the carrier concentrations of the source region and the drain region with high accuracy and a poor operation of the transistor caused by insufficient control of concentration of an electric field.

Taking the above circumstances into consideration, a technology that can realize higher reliability in operations of a transistor has been demanded. Thus, the present disclosure proposes a novel and improved semiconductor device, display device, and manufacturing method of the semiconductor device that can realize higher reliability.

According to an embodiment of the present disclosure, there is provided a semiconductor device including a first region which is, in an oxide semiconductor layer, a region having a higher carrier concentration than a channel region immediately below a gate electrode formed over the oxide semiconductor layer and is formed at least in a partial region other than the channel region, and a second region which is, in the oxide semiconductor layer, a region having a higher carrier concentration than the first region and is formed farther from the channel region than the first region. The first region is formed through a first reduction reaction by stacking a first reduction reaction film over the oxide semiconductor layer and reducing the oxide semiconductor layer by the first reduction reaction film. The second region is formed through a second reduction reaction by stacking a second reduction reaction film over the oxide semiconductor layer and reducing the oxide semiconductor layer by the second reduction reaction film.

According to another embodiment of the present disclosure, there is provided a display device in which a thin film transistor is used as a pixel driving element, the transistor including a first region which is, in an oxide semiconductor layer, a region having a higher carrier concentration than a channel region immediately below a gate electrode formed over the oxide semiconductor layer and is formed at least in a partial region other than the channel region, and a second region which is, in the oxide semiconductor layer, a region having a higher carrier concentration than the first region and is formed farther from the channel region than the first region. The first region is formed through a first reduction reaction by stacking a first reduction reaction film over the oxide semiconductor layer and reducing the oxide semiconductor layer by the first reduction reaction film. The second region is formed through a second reduction reaction by stacking a second reduction reaction film over the oxide semiconductor layer and reducing the oxide semiconductor layer by the second reduction reaction film.

According to another embodiment of the present disclosure, there is provided a manufacturing method of a semiconductor device, the manufacturing method including stacking a first reduction reaction film over an oxide semiconductor layer, then performing a first reduction reaction to reduce the oxide semiconductor layer using the first reduction reaction film, and forming, in the oxide semiconductor layer, a first region having a higher carrier concentration than a channel region immediately below a gate electrode formed over the oxide semiconductor layer at least in a partial region other than the channel region, and stacking a second reduction reaction film over the oxide semiconductor layer, then performing a second reduction reaction to reduce the oxide semiconductor layer using the second reduction reaction film, and forming, in the oxide semiconductor layer, a second region having a higher carrier concentration than the first region farther from the channel region than the first region.

According to one or more of embodiments of the present disclosure, a first region having a higher carrier concentration than a channel region immediately below a gate electrode and a second region having a higher carrier concentration than the first region are provided in an oxide semiconductor layer, and thereby phased carrier concentration distribution is realized. In addition, since the first region and the second region are formed by reducing the oxide semiconductor layer using a first reduction reaction film and a second reduction reaction film, formation positions of the first region and the second region can be controlled with high accuracy. Thus, desired carrier concentration distribution inside the oxide semiconductor layer can be formed with higher accuracy, and accordingly reliability of a semiconductor device can be further improved.

According to one or more of embodiments of the present disclosure described above, higher reliability can be realized. Note that the effect described above is not necessarily limiting, and along with or instead of the effect, any effect that is desired to be introduced in the present specification or other effects that can be expected from the present specification may be exhibited.

### BRIEF DESCRIPTION OF THE DRAWINGS

FIG. 1A is a cross-sectional diagram showing an example of a manufacturing method of a semiconductor device according to a first embodiment of the present disclosure;

FIG. 1B is a cross-sectional diagram showing an example of a manufacturing method of a semiconductor device according to the first embodiment of the present disclosure;

FIG. 1C is a cross-sectional diagram showing an example of a manufacturing method of a semiconductor device according to the first embodiment of the present disclosure;

FIG. 1D is a cross-sectional diagram showing an example of a manufacturing method of a semiconductor device according to the first embodiment of the present disclosure;

FIG. 1E is a cross-sectional diagram showing an example of a manufacturing method of a semiconductor device according to the first embodiment of the present disclosure;

FIG. 1F is a cross-sectional diagram showing an example of a manufacturing method of a semiconductor device according to the first embodiment of the present disclosure;

FIG. 1G is a cross-sectional diagram showing an example of a manufacturing method of a semiconductor device according to the first embodiment of the present disclosure;

FIG. 2A is a cross-sectional diagram showing an example of a manufacturing method of a semiconductor device according to a second embodiment of the present disclosure;

FIG. 2B is a cross-sectional diagram showing an example of a manufacturing method of a semiconductor device according to the second embodiment of the present disclosure;

FIG. 2C is a cross-sectional diagram showing an example of a manufacturing method of a semiconductor device according to the second embodiment of the present disclosure;

FIG. 3A is a cross-sectional diagram showing an example of a manufacturing method of a semiconductor device according to a third embodiment of the present disclosure;

FIG. 3B is a cross-sectional diagram showing an example of a manufacturing method of a semiconductor device according to the third embodiment of the present disclosure;

FIG. 3C is a cross-sectional diagram showing an example of a manufacturing method of a semiconductor device according to the third embodiment of the present disclosure;

FIG. 3D is a cross-sectional diagram showing an example of a manufacturing method of a semiconductor device according to the third embodiment of the present disclosure;

FIG. 4 is a cross-sectional diagram showing an example of a manufacturing method of a semiconductor device according to a fourth embodiment of the present disclosure;

FIG. 5 is a cross-sectional diagram of an organic EL display device to which a TFT according to the first embodiment is applied showing a schematic configuration of a region corresponding to one pixel;

FIG. 6 is a schematic diagram of a circuit configuration of the organic EL display device to which the TFT according to the first embodiment is applied;

FIG. 7 is a schematic diagram showing a configuration of a periphery circuit of one pixel of the circuit configuration shown in FIG. 6 in detail;

FIG. 8 is a schematic diagram of a liquid crystal display device to which a TFT according to the first embodiment is applied showing a schematic configuration of a region corresponding to one pixel;

FIG. 9 is a schematic diagram showing a circuit configuration of the liquid crystal display device to which the TFT according to the first embodiment is applied;

FIG. 10 is a schematic diagram showing a configuration of a periphery circuit of one pixel of the pixel configuration shown in FIG. 9 in detail;

FIG. 11 is a schematic diagram showing a stacking structure of a CMOS image sensor to which a TFT 80 according to a modified example having a bottom-gate configuration is applied;

FIG. 12 is a cross-sectional diagram of the CMOS image sensor to which the TFT according to the modified example is applied showing a schematic configuration of a region corresponding to one pixel;

FIG. 13 is a schematic diagram showing a circuit configuration of the CMOS image sensor to which the TFT according to the modified example is applied;

FIG. 14 is an external diagram of a smartphone to which the organic EL display device, the liquid crystal display device and/or the CMOS image sensor are applied;

FIG. 15 is an external diagram of a display device to which the organic EL display device or the liquid crystal display device is applied; and

FIG. 16 is an external diagram of an imaging device to which the organic EL display device, the liquid crystal display device and/or the CMOS image sensor are applied.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Note that description will be provided in the following order.

1. First embodiment
1-1. Structure and manufacturing method of a semiconductor device
1-2. Comparison to an existing semiconductor device
1-3. Modified examples
   1-3-1. Modified example in which a first reduction reaction film and a second reduction reaction film are formed of the same material
   1-3-2. Modified example in which a sidewall is not provided

2. Second embodiment
2-1. Structure and manufacturing method of a semiconductor device

3. Third embodiment
3-1. Structure and manufacturing method of a semiconductor device

4. Fourth embodiment
4-1. Structure and manufacturing method of a semiconductor device

5. Application examples
5-1. Application to an organic EL display device
5-2. Application to a liquid crystal display device
5-3. Application to an image sensor
5-4. Application to electronic apparatuses having display devices

6. Supplement

Herein, a semiconductor device can include any of various kinds of elements, devices, modules, units, and the like that can function using characteristics of a semiconductor in the present specification. Hereinbelow, a case in which the semiconductor device is a thin film transistor (TFT) will be exemplified as a semiconductor device according to an embodiment of the present disclosure. The present embodiment, however, is not limited thereto, and the semiconductor device according to the present embodiment may be any of various kinds of elements, devices, modules, units, and the like.

### 1. First Embodiment

### 1-1. Structure and Manufacturing Method of a Semiconductor Device

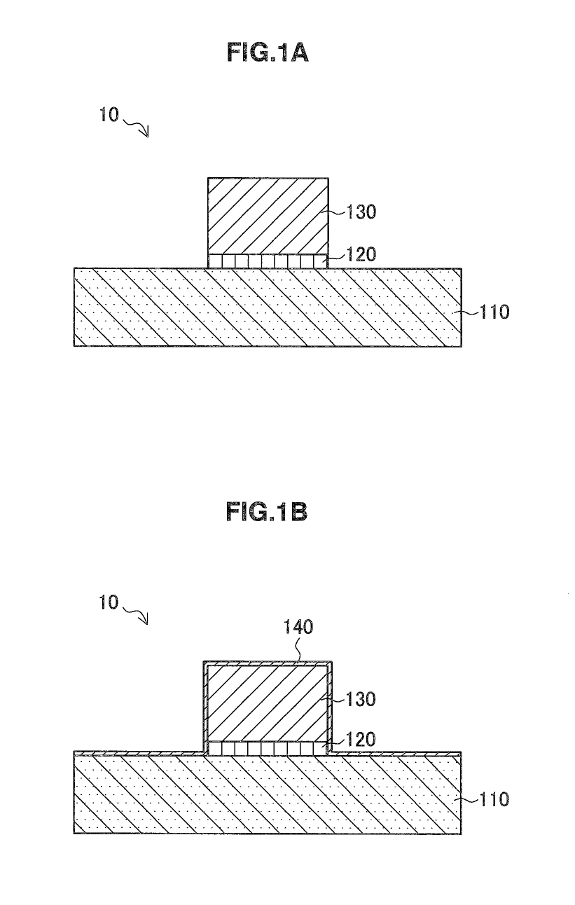

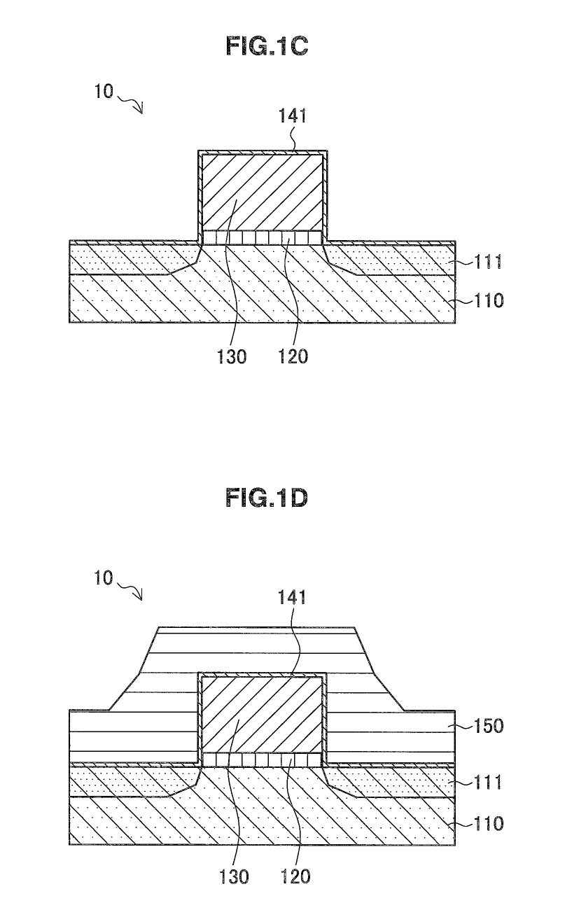

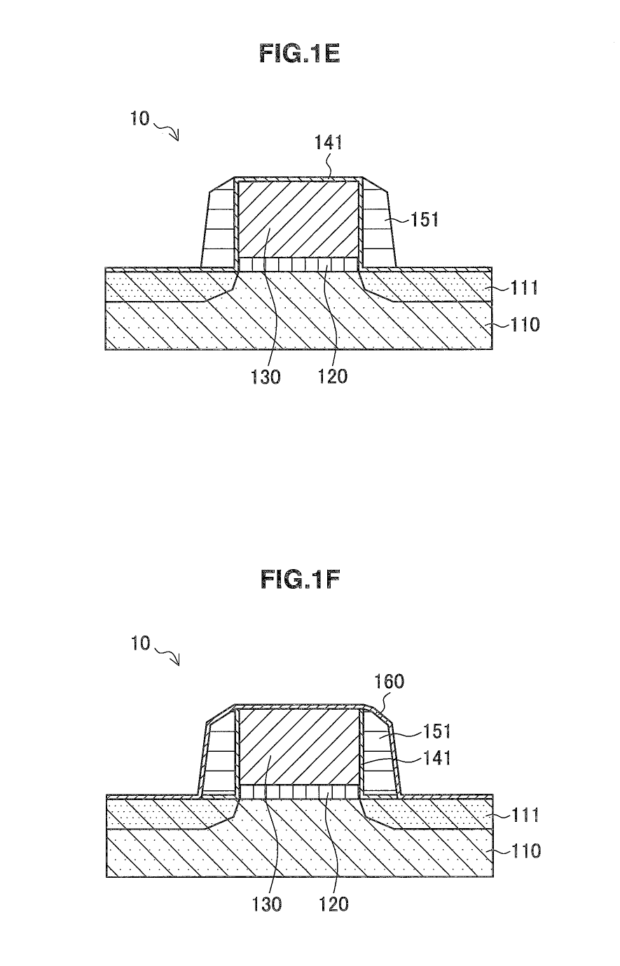

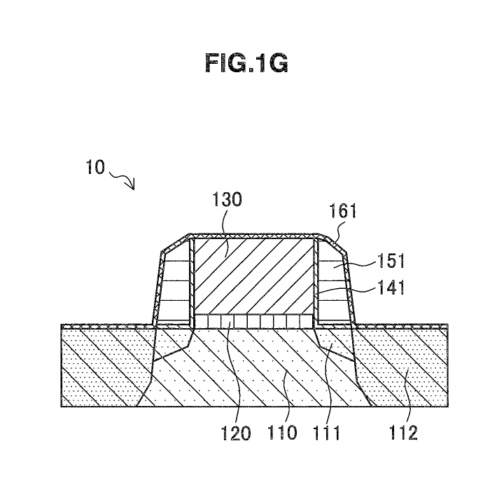

First, a structure and a manufacturing method of a semiconductor device according to a first embodiment of the present disclosure will be described with reference to FIGS. 1A to 1G FIGS. 1A to 1G are cross-sectional diagrams showing an example of the manufacturing method of the semiconductor device according to the first embodiment of the present disclosure. FIGS. 1A to 1G schematically illustrate a cross-section of a TFT 10 that is the semiconductor device according to the first embodiment in a channel direction in order of steps of the manufacturing method of the semiconductor device, showing a process flow of the manufacturing method. Hereinbelow, the process flow of the manufacturing method of the semiconductor device according to the first embodiment will be described in order with reference to FIGS. 1A to 1G.

In the manufacturing method of the TFT 10 according to the first embodiment, first, a gate insulation film 120 and a gate electrode 130 are stacked over an oxide semiconductor layer 110 as shown in FIG. 1A, and the gate insulation film 120 and the gate electrode 130 are processed so as to have a predetermined gate length. Note that, although not illustrated in FIGS. 1A to 1G for the sake of simplification, the TFT 10 is formed over a substrate such as a glass substrate or a plastic substrate in reality, and accordingly the oxide semiconductor layer 110 is stacked over the substrate. A configuration of the TFT 10 formed over a substrate will be described in <5. Application examples> below in detail.

The oxide semiconductor layer 110 is formed of a material that includes, for example, indium (In), gallium (Ga), zinc (Zn), and oxygen (an In—Ga—Zn—O-based material). The In—Ga—Zn—O-based material can realize higher carrier mobility in comparison to materials such as polycrystalline silicon (Si), amorphous silicon, and organic material semiconductors that are generally used in existing transistors. By using the In—Ga—Zn—O-based material for the oxide semiconductor layer 110 in the first embodiment, performance of the TFT 10 can be further improved.

The first embodiment, however, is not limited to the above, and other materials can be used for the oxide semiconductor layer 110. As will be described later, by causing an oxidation-reduction reaction between the oxide semiconductor layer 110 and a film that triggers a reduction reaction with the oxide semiconductor layer 110 (which will be referred to hereinafter as a reduction reaction film) in the first embodiment, a carrier concentration inside the oxide semiconductor layer 110 is adjusted. Thus, as the oxide semiconductor layer 110, a material that reacts to the reduction reaction film that will be described later and thereby exhibits a reduction reaction can be selected.

The oxide semiconductor layer 110 may be formed of at least one or more materials selected from materials such as an In—O-based material, a Ga—O-based material, a Zn—O-based material, and a Sn—O-based material, binary metal oxides including an In—Zn—O-based material, a Sn—Zn—O-based material, an Al—Zn—O-based material, a Zn—Mg—O-based material, a Sn—Mg—O-based material, an In—Mg—O-based material, and an In—Ga—O-based material, ternary metal oxides including an In—Ga—Zn—O-based material, an In—Al—Zn—O-based material, an In—Sn—Zn—O-based material, a Sn—Ga—Zn—O-based material, an Al—Ga—Zn—O-based material, a Sn—Al—Zn—O-based material, an In—Hf—Zn—O-based material, an In—La—Zn—O-based material, an In—Ce—Zn—O-based material, an In—Pr—Zn—O-based material, an In—Nd—Zn—O-based material, an In—Sm—Zn—O-based material, an In—Eu—Zn—O-based material, an In—Gd—Zn—O-based material, an In—Tb—Zn—O-based material, an In—Dy—Zn—O-based material, an In—Ho—Zn—O-based material, an In—Er—Zn—O-based material, an In—Tm—Zn—O-based material, an In—Yb—Zn—O-based material, an In—Lu—Zn—O-based material, and an In—Ni—Zn—O-based material, quaternary metal oxides including an In—Sn—Ga—Zn—O-based material, an In—Hf—Ga—Zn—O-based material, an In—Al—Ga—Zn—O-based material, an In—Sn—Al—Zn—O-based material, an In—Sn—Hf—Zn—O-based material, and an In—Hf—Al—Zn—O-based material, and the like.

The gate insulation film 120 can be formed of, for example, a silicon oxide. The first embodiment, however, is not limited thereto, and any of various kinds of materials that are generally used as a gate insulation film of a field effect transistor may be applied to the gate insulation film 120. The gate insulation film 120 may be formed of, for example, at least one or more materials selected from insulating materials including a silicon nitride, a silicon oxy-nitride, and the like. Note that a thickness of the gate insulation film 120 may be appropriately designed according to desired performance of the TFT 10. In addition, as a specific process of forming the gate insulation film 120, various kinds of processes that are generally used in forming a gate insulation film of a field effect transistor may be applied, and thus detailed description thereof will be omitted.

The gate electrode 130 can be formed of at least one or more materials selected from conductive materials such as molybdenum (Mo), tungsten (W), a titanium nitride, ruthenium (Ru), a tantalum silicon nitride film, aluminum (Al), polysilicon, and the like. The first embodiment, however, is not limited thereto, and as the gate electrode 130, any of various kinds of materials that are generally used as a gate electrode of a field effect transistor may be applied. In addition, as a specific process of forming the gate electrode 130, various kinds of processes that are generally used in forming a gate electrode of a field effect transistor may be applied, and thus detailed description thereof will be omitted.

Next, a first reduction reaction film 140 is stacked over the oxide semiconductor layer 110 and the gate electrode 130 as shown in FIG. 1B. Here, the first reduction reaction film 140 has a function of causing an oxidation-reduction reaction with the oxide semiconductor layer 110 that is at least in contact therewith through heat treatment that will be described later and thereby reducing the oxide semiconductor layer 110. Note that, when the first reduction reaction film 140 reduces the oxide semiconductor layer 110, the first reduction reaction film 140 may not necessarily be in direct contact with the oxide semiconductor layer 110. For example, even when the oxide semiconductor layer 110 and the first reduction reaction film 140 are stacked with a thin film having a thickness of about several nm interleaved therebetween, the oxide semiconductor layer 110 can be reduced by the first reduction reaction film 140.

The first reduction reaction film 140 can be formed of, for example, silicon. The first embodiment, however, is not limited thereto, and as the first reduction reaction film 140, any of other materials may be applied as long as it has the function of reducing the oxide semiconductor layer 110 by causing an oxidation-reduction reaction with the oxide semiconductor layer 110 that is formed of the various kinds of materials described above. The first reduction reaction film 140 may be formed of at least one or more materials selected from metal materials such as magnesium (Mg), aluminum, silicon, titanium (Ti), vanadium (V), chromium (Cr), manganese (Mn), cobalt (Co), nickel (Ni), yttrium (Y), zirconium (Zr), niobium (Nb), molybdenum, cerium (Ce), neodymium (Nd), hafnium (Hf), tantalum (Ta), tungsten, and the like.

In addition, the first reduction reaction film 140 can be formed through various kinds of processes used in stacking a metal material in a general semiconductor process, for example, a vapor deposition method, a CVD method, a sputtering method, and the like. The first reduction reaction film 140 is formed to a thickness of, for example, about 1 to 10 nm.

Next, heat treatment is performed on the configuration shown in FIG. 1B at a heating temperature of, for example, about 100 to 300 degrees Celsius. Through the heat treatment, an oxidation-reduction reaction occurs at least in the region between the oxide semiconductor layer 110 and the first reduction reaction film 140 coming in contact with each other. Here, materials of the oxide semiconductor layer 110 and the first reduction reaction film 140 are appropriately selected so that oxygen moves from the oxide semiconductor layer 110 to the first reduction reaction film 140, in other words, so that the first reduction reaction film 140 is oxidized and the oxide semiconductor layer 110 is reduced. Note that, in description below, the reaction in which the oxide semiconductor layer 110 is reduced by the first reduction reaction film 140 is also referred to as a first reduction reaction.

FIG. 1C shows a structure of the TFT 10 after the heat treatment. As a result of the occurrence of the reduction reaction, first regions 111 that are regions in which a carrier concentration has increased more than other regions are formed at least in the region in which the first reduction reaction film 140 is in contact with the oxide semiconductor layer 110 (to be specific, the region in which the gate electrode 130 is not formed).

In addition, as a result of the occurrence of the oxidation reaction, the first reduction reaction film 140 changes into a first reaction product 141. The first reaction product 141 can be an oxide of the material composing the first reduction reaction film 140. For example, since the first reduction reaction film 140 is formed of silicon in the example shown in FIG. 1C, the first reaction product 141 can be a silicon oxide (SiO₂). Note that the example shown in FIG. 1C illustrates that the entire first reduction reaction film 140 changes into the first reaction product 141 since the first reduction reaction film 140 is formed as a relatively thin film, but the first reaction product 141 may actually be generated in a region of the first reduction reaction film 140 at a predetermined depth from the location of the oxide semiconductor layer 110 and the gate electrode 130.

Herein, in the first embodiment, since the first reduction reaction film 140 is stacked after the gate insulation film 120 and the gate electrode 130 are formed over the oxide semiconductor layer 110, the first reduction reaction film 140 hardly brings the oxidation-reduction reaction with the oxide semiconductor layer 110 in the region immediately below the gate electrode 130 (i.e., a channel region), but reduces the oxide semiconductor layer 110 in other regions which can be a source region and a drain region. Thus, the first regions 111 in which the carrier concentration has increased are generated mainly in the regions which can be the source region and the drain region, and are hardly formed in the channel region. Therefore, in the oxide semiconductor layer 110, a carrier concentration distribution in which the source region and the drain region have a higher carrier concentration than the channel region is realized.

As described above, in the first embodiment, the carrier concentration distribution in which the carrier concentration is relatively low in the channel region immediately below the gate electrode, and the carrier concentration is relatively high in the remaining source or drain regions is realized in the oxide semiconductor layer 110. Accordingly, switching caused by a bias voltage that is applied to the gate electrode is possible with a relatively low voltage, and an implantation amount of carriers into the channel (i.e., an amount of a channel current) at the time of the bias voltage application can be increased more. Therefore, the TFT 10 with higher performance can be obtained.

Here, the carrier concentration of the first regions 111 and the depth at which the first regions 111 are formed can be adjusted by appropriately controlling, for example, the materials of the oxide semiconductor layer 110 and the first reduction reaction film 140, the thickness of the first reduction reaction film 140, and parameters relating to the oxidation-reduction reaction such as temperature, time, atmosphere, and the like of the heat treatment. By appropriately adjusting the parameters, the first regions 111 that have a desired carrier concentration and formation depth can be formed. For example, a thicker thickness of the first reduction reaction film 140, a higher heating temperature in the heat treatment, and a longer heating time in the heat treatment are considered to promote the oxidation-reduction reaction and increase a carrier density and a formation depth of the first regions 111.

When the oxidation-reduction reaction by the first reduction reaction film 140 ends, an insulation film 150 is next formed on the oxide semiconductor layer 110 and the gate electrode 130 in an isotropic manner as shown in FIG. 1D. The insulation film 150 may be formed of the same material as the gate insulation film 120, and thus is, for example, a silicon oxide. Further, as shown in FIG. 1E, the insulation film 150 is selectively removed through anisotropic etching, for example, a dry etching method or the like, and then a sidewall insulation film 151 (a so-called sidewall 151) is formed along the side surface portion of the gate electrode 130. Note that, since the series of processes shown in FIGS. 1D and 1E may be performed using, for example, various kinds of processes used when a sidewall is formed in a gate structure in a general semiconductor process, detailed description thereof will be omitted.

Next, a second reduction reaction film 160 is stacked over the oxide semiconductor layer 110, the gate electrode 130, and the sidewall 151 as shown in FIG. 1F. Same as the first reduction reaction film 140, the second reduction reaction film 160 has a function of causing an oxidation-reduction reaction with the oxide semiconductor layer 110 that is at least in contact therewith through the heat treatment and thereby reducing the oxide semiconductor layer 110. Note that, as shown in FIG. 1F, it is preferable to at least remove the first reaction product 141 that is exposed on a surface of the oxide semiconductor layer 110 using, for example, an etching method or the like before a second reduction reaction film 160 is stacked. Note that, when the second reduction reaction film 160 reduces the oxide semiconductor layer 110, the second reduction reaction film 160 may not necessarily be in direct contact with the oxide semiconductor layer 110. For example, even when the oxide semiconductor layer 110 and the second reduction reaction film 160 are stacked with a thin film having a thickness of about several nm interleaved therebetween, the oxide semiconductor layer 110 can be reduced by the second reduction reaction film 160.

The second reduction reaction film 160 can be formed of the same materials as those exemplified in the above description as materials of which the first reduction reaction film 140 can be formed. In the first embodiment, for example, the second reduction reaction film 160 is formed of aluminum. Herein, aluminum is known to have a reaction property (reduction property) in a reduction reaction that is higher than that of silicon that is the material of the first reduction reaction film 140. When the second reduction reaction film 160 is formed of a material different from that of the first reduction reaction film 140 as described above, it is preferable to form the second reduction reaction film 160 using a material having a reduction property higher than that of the first reduction reaction film 140. The first embodiment, however, is not limited thereto, and the second reduction reaction film 160 may be formed of the same material as the first reduction reaction film 140. The case in which the first reduction reaction film 140 and the second reduction reaction film 160 are formed of the same material will be described in [1-3. Modified examples] below in detail.

Next, heat treatment is performed on the configuration shown in FIG. 1F at a heating temperature of, for example, about 100 to 300 degrees Celsius. Due to the heat treatment, an oxidation-reduction reaction occurs between the oxide semiconductor layer 110 and the second reduction reaction film 160 at least in a region in which they come in contact with each other. Here, as in the case of the first reduction reaction film 140, materials of the oxide semiconductor layer 110 and the second reduction reaction film 160 are appropriately selected so that the second reduction reaction film 160 is oxidized and the oxide semiconductor layer 110 is reduced. Note that, in the following description, the reaction in which the second reduction reaction film 160 reduces the oxide semiconductor layer 110 is also referred to as a second reduction reaction.

FIG. 1G shows a structure of the TFT 10 after the heat treatment. As a result of the occurrence of the reduction reaction, second regions 112 that are regions in which a carrier concentration has increased more than other regions are formed at least in the region of the oxide semiconductor layer 110 coming in contact with the second reduction reaction film 160 (to be specific, the region in which the gate electrode 130 and the sidewall 151 are not formed). As shown in FIG. 1F, the second reduction reaction film 160 is stacked such that a part thereof overlaps a region on a surface of the oxide semiconductor layer 110 in which the first regions 111 are formed. Since the region of the oxide semiconductor layer 110 immediately below the second reduction reaction film 160 is reduced from the heat treatment, the second regions 112 become regions having a carrier concentration higher than that of the first regions 111 in which an increase amount of the carrier concentration with regard to the first reduction reaction film 140 and an increase amount of the carrier concentration with regard to the second reduction reaction film 160 are combined.

In the heat treatment performed when the second regions 112 are to be formed, it may be required to induce another reduction reaction on the region in which the first regions 111 have already been formed, however, a material having a reduction property higher than that of the first reduction reaction film 140 can be preferably selected for the material of the second reduction reaction film 160 as described above, and thus the reduction reaction caused by the heat treatment is more easily promoted and the second regions 112 are formed more easily. Note that, even when the second reduction reaction film 160 is stacked over the surface of the oxide semiconductor layer 110 with the first reaction product 141 remaining, it is possible to promote the oxidation-reduction reaction between the oxide semiconductor layer 110 and the second reduction reaction film 160 having the first reaction product 141 therebetween and thereby to form the second regions 112 by appropriately adjusting the material or the thickness of the second reduction reaction film 160, a condition of the heat treatment, or the like.

In addition, as a result of the occurrence of the oxidation reaction, the second reduction reaction film 160 changes into a second reaction product 161. The second reaction product 161 can be an oxide of the material composing the second reduction reaction film 160. For example, since the second reduction reaction film 160 is formed of aluminum in the example shown in FIG. 1G, the second reaction product 161 can be an aluminum oxide (Al₂O₃). Note that the example shown in FIG. 1G illustrates that the entire second reduction reaction film 160 changes into the second reaction product 161 since the second reduction reaction film 160 is formed as a relatively thin film, but the second reaction product 161 may actually be generated in a region of the second reduction reaction film 160 at a predetermined depth from the location of the oxide semiconductor layer 110 and the gate electrode 130.

In the TFT 10, the second regions 112 are used as a source region and a drain region. A source electrode (not illustrated) for giving predetermined electric potential to the source region and a drain electrode (not illustrated) for giving predetermined electric potential to the drain region are formed in the respective second regions 112 having the gate electrode 130 therebetween, and thereby the TFT 10 according to the first embodiment is completed.

Hereinabove, the structure and the manufacturing method of the TFT 10 according to the first embodiment have been described with reference to FIGS. 1A to 1G Next, carrier concentration distribution in the oxide semiconductor layer 110 of the TFT 10 will be described in detail.

As described above, the gate insulation film 120, the gate electrode 130, and the sidewall 151 are formed over the oxide semiconductor layer 110, and then the second reduction reaction film 160 is stacked thereon in the first embodiment. Thus, the second reduction reaction film 160 hardly causes an oxidation-reduction reaction with the oxide semiconductor layer 110 in the region immediately below the gate electrode 130 and the sidewall 151, and reduces the oxide semiconductor layer 110 in other regions. Accordingly, the second regions 112 in which the carrier concentration has increased are generated mainly in the region in which the gate electrode 130 and the sidewall 151 are not formed, and are hardly generated in other regions.

In addition, as described with reference to FIG. 1C, the first reduction reaction film 140 hardly causes the oxidation-reduction reaction with the oxide semiconductor layer 110 in the region immediately below the gate electrode 130, and reduces the oxide semiconductor layer 110 in other regions, and thus the first regions 111 are generated mainly in the region other than the channel region immediately below the gate electrode 130.

Hence, the carrier concentration inside the oxide semiconductor layer 110 of the TFT 10 has the distribution in which the channel region has the lowest concentration and the carrier concentration gradually increases toward the first regions 111 that are formed in the region immediately below the sidewall 151 and the second regions 112 that are formed in the region other than the aforementioned region. Thus, as the second regions 112 are used as the source region and the drain region, a channel in which the carrier concentration is lowered from the source region and the drain region toward the gate electrode 130 in stages is formed, and accordingly concentration of an electric field on the edges of the source region and the drain region abutting the gate electrode 130 is alleviated. Therefore, according to the first embodiment, it is possible to suppress a poor operation of the TFT 10 due to concentration of an electric field and thereby to form the TFT 10 having higher reliability.

Further, the formation positions of the first regions 111 and the second regions 112 are decided according to the regions in which the first reduction reaction film 140 and the second reduction reaction film 160 come in contact with the oxide semiconductor layer 110 or a region that is close enough for an oxidation-reduction reaction to be caused with another layer therebetween. On the other hand, since the first reduction reaction film 140 is stacked after the gate electrode 130 is formed, and the second reduction reaction film 160 is stacked after the sidewall 151 is formed in the first embodiment, regions of the oxide semiconductor layer 110 reduced by the first reduction reaction film 140 and the second reduction reaction film 160 are decided according to the formation positions of the gate electrode 130 and the sidewall 151. In other words, according to shapes of the gate electrode 130 and the sidewall 151, the boundary of the channel region and the first regions 111 and the boundary of the first regions 111 and the second regions 112 are demarcated through so-called self-alignment. Since the formation positions of the first regions 111 and the second regions 112 can be decided according to the formation positions of the gate electrode 130 and the sidewall 151 in the first embodiment as described above, it is possible to decide positions in which the carrier concentration gradually changes (for example, the boundary of the channel region and the first regions 111) with high accuracy, and thereby the TFT 10 having higher reliability is realized.

Note that, in the first embodiment, concentration distribution in which the carrier concentration is lowered in the oxide semiconductor layer 110 from the source region and the drain region toward the gate electrode 130 in stages may be formed, and a decision method of the formation positions of the first regions 111 and the second regions 112 is not limited to the method according to the formation positions of the gate electrode 130 and the sidewall 151 described above. In order to realize such carrier concentration distribution, the first regions 111 that are regions having a higher carrier concentration than the channel region are formed at least in a partial region other than the channel region, the second regions 112 having a higher carrier concentration than the first regions 111 may be formed farther from the channel region than the first regions 111 in the oxide semiconductor layer 110 in the first embodiment, and the formation positions of the first regions 111 and the second regions 112 are arbitrary. For example, a formation method of the first regions 111 and the second regions 112 without using the sidewall 151 will be described in detail in [1-3. Modified examples] below.

Herein, in the example shown in FIGS. 1A to 1G, the configuration of the TFT 10 in which, before the second reduction reaction film 160 is stacked, the first reaction product 141 that is exposed at least on the surface of the oxide semiconductor layer 110 is removed using, for example, the etching method, or the like is illustrated. The first embodiment, however, is not limited thereto, and the second reduction reaction film 160 may be stacked without removing the first reaction product 141 that is exposed on the surface of the oxide semiconductor layer 110, and then the second regions 112 may be formed. When the second reduction reaction film 160 is stacked without removing the first reaction product 141, the first reaction product 114 is stacked in the region in which the first regions 111 are formed on the surface of the oxide semiconductor layer 110, and the first reaction product 141 and the second reaction product 161 are stacked in the region in which the second regions 112 are formed on the surface of the oxide semiconductor layer 110, and thus a level difference is generated on the surface of the oxide semiconductor layer 110.

In addition, even if the second reduction reaction film 160 is stacked after removing the first reaction product 141, thicknesses of the first reaction product 141 and the reaction product 161 are different from each other or degrees of erosion of the oxide semiconductor layer 110 are different due to the difference in the reduction properties of the first reduction reaction film 140 and the second reduction reaction film 160, and therefore the level difference between the region in which the first regions 111 are formed and the region in which the second regions 112 are formed is reliably generated on the surface of the oxide semiconductor layer 110.

In general, the level difference is considered to have an extremely small influence on an electrical characteristic of the TFT 10. When, however, the influence of the level difference on the electrical characteristic of the TFT 10 is not negligible in light of application of the TFT 10 and the like, a process of decreasing the level difference may be appropriately performed. As such a process of decreasing the level difference, for example, methods of adjusting the degree of erosion of the oxide semiconductor layer 110 at the time of the oxidation-reduction reaction by changing the materials of the first reduction reaction film 140 and the second reduction reaction film 160, or adjusting the thicknesses of the first reaction product 141 and the second reaction product 161 by changing the thicknesses of the first reduction reaction film 140 and the second reduction reaction film 160 are considered. If, however, the materials and the thicknesses of the first reduction reaction film 140 and the second reduction reaction film 160 are changed, there is a possibility of the carrier concentrations of the first regions 111 and the second regions 112 also changing, and thus it is desirable to perform the process of decreasing the level difference on the surface of the oxide semiconductor layer 110 also taking the change in the carrier concentrations into account.

### 1-2. Comparison to an Existing Semiconductor Device

Herein, the TFT 10 according to the first embodiment described above will be compared to an existing general TFT. First, the result obtained after the present inventors examined the existing general TFT will be described.

In recent years, as a TFT that is used in electronic apparatuses such as display devices, a TFT that uses an oxide semiconductor of a transparent thin film made of an In—Ga—Zn—O-based material or the like (an oxide semiconductor TFT) has gained attention. The oxide semiconductor TFT can realize higher carrier mobility than a TFT that uses other materials, for example, polycrystalline silicon, and the like. On the other hand, there is a possibility in an oxide semiconductor having a relatively lower carrier concentration than a material such as polycrystalline silicon and not obtaining a desired channel current when it is used for a TFT without any processing. In addition, as a general process performed to increase a carrier concentration of a material, an impurity injection process using ion implantation is known, however, the oxide semiconductor is known to have a low effect of increasing the carrier concentration using ion implantation in comparison to other materials such as polycrystalline silicon. Therefore, when the carrier concentration inside the oxide semiconductor using ion implantation is adjusted, it is necessary to implant a larger dosage of ions in comparison to other general materials, and therefore there is a possibility of a manufacturing cost increasing.

For this reason, a method of adjusting a carrier concentration inside an oxide semiconductor using an oxidation-reduction reaction rather than ion implantation has been proposed as disclosed in “A Novel Self-Aligned Top-Gate Oxide TFT for AM-OLED Displays” described above. In this method, a metal thin film is stacked over an oxide semiconductor layer over which a gate insulation film and a gate electrode are formed, and by performing appropriate heat treatment, an oxidation-reduction reaction is caused between the oxide semiconductor layer and the metal thin film in a region in which they come in contact with each other. By reducing the oxide semiconductor layer through the oxidation reduction reaction, the carrier concentration inside the oxide semiconductor layer increases. In this manner, according to the technology disclosed in “A Novel Self-Aligned Top-Gate Oxide TFT for AM-OLED Displays,” carrier concentration distribution in which a channel region of the oxide semiconductor layer immediately below the gate electrode has a relatively low carrier concentration and a source region and a drain region other than that has a relatively high carrier concentration is realized.

On the other hand, as a TFT that is used for driving pixels in a display device, in general, a bottom-gate TFT in which a gate electrode is formed in a lower portion of a semiconductor layer and a source region and a drain region are formed in an upper portion of the semiconductor layer is mainly used. In recent years, however, from the viewpoint of attempting cost reduction by reducing the number of steps, a top-gate TFT in which a gate electrode, a source region, and a drain region are formed on an upper portion of a semiconductor layer has been reviewed as a substitute for such a bottom-gate TFT.

Since manufacturing steps of a top-gate TFT can be simplified in comparison to a bottom-gate TFT, a reduction in the number of steps and improvement in yield are expected. However, there is a concern in the top-gate TFT of the distance between the gate electrode and a source electrode and/or a drain electrode being short and accordingly the intensity of an electric field becoming strong in the edges of the source region and/or the drain region close to the gate electrode in comparison to the bottom-gate TFT. Such concentration of the electric field on the edges of the source region and/or the drain region abutting the gate electrode has a possibility of causing a poor operation of the TFT, which is not favorable in terms of reliability of the TFT.

Thus, in order to gain a TFT having higher reliability, JP 2013-48217A described above has proposed a method of alleviating the intensity of an electric field occurring between a gate electrode and a source region and/or a drain region by using a sidewall. In this method, after the gate electrode and the sidewall are formed over an oxide semiconductor layer, impurity injection using ion implantation is performed from the top of the gate electrode and the sidewall, and accordingly a gradient of carrier concentrations occurs in a region in the oxide semiconductor layer immediately below the sidewall and a region in which the gate electrode and the sidewall are not present. According to the method, there is a possibility of an intensity of an electric field between the gate electrode and the source region and/or the drain region alleviated. However, it is difficult to control the carrier concentration inside the oxide semiconductor layer using the ion implantation performed from the top of the sidewall with high accuracy. Therefore, in the method disclosed in JP 2013-48217A, there is a possibility of desired carrier concentration distribution inside the oxide semiconductor layer not being formed.

So far, the result obtained after the present inventors examined the existing general TFT has been described. Through the course of serious examinations on a technology for more effectively alleviating an intensity of an electric field occurring between a gate electrode and a source region and/or a drain region by controlling carrier concentration distribution inside an oxide semiconductor layer with high accuracy based on the above examination result with respect to the existing general technologies, the present inventors have achieved the first embodiment described above, as well as second, third, and fourth embodiments.

As described in [1-1. Structure and manufacturing method of a semiconductor device] above, according to the first embodiment, the first regions 111 which are regions having a carrier concentration higher than that of the channel region which is a region immediately below the gate electrode 130 are formed at least in partial regions in the oxide semiconductor layer 110 rather than in the channel region. In addition, the second regions 112 that have a higher carrier concentration than the first regions 111 are formed in regions farther from the channel region than the first regions 111. Accordingly, in the TFT 10 according to the first embodiment, the carrier concentration distribution in which carrier concentrations decrease from the second regions 112 toward the channel region in stages is realized. Thus, by forming a source electrode or a drain electrode in the second regions 112 and using a predetermined region which at least includes the first regions 111 and the second regions 112 as the source region and the drain region, concentration of an electric field on the edges of the source region and/or the drain region abutting the gate electrode 130 in the channel direction is alleviated and more stabilized driving of the TFT 10 is realized.

In addition, in the first embodiment, the first regions 111 and the second regions 112 are formed when the first reduction reaction film 140 and the second reduction reaction film 160 reduce the oxide semiconductor layer 110. Thus, the formation positions of the first regions 111 and the second regions 112 can be decided at least based on, for example, the stacking positions of the first reduction reaction film 140 and the second reduction reaction film 160. In addition, the carrier concentrations and formation depths of the first regions 111 and the second regions 112 can be decided at least based on, for example, the materials and thicknesses of the first reduction reaction film 140 and the second reduction reaction film 160, and conditions of the heat treatment (a heating time, a heating temperature, and the like) at the time of the oxidation reduction reaction. Since the parameters of the stacking positions and thicknesses of the first reduction reaction film 140 and the second reduction reaction film 160, the conditions of the heat treatment at the time of the oxidation reduction reaction, and the like can be controlled with high accuracy relatively easily in an existing process, it is possible to control the formation positions, formation depths, and/or carrier concentrations of the first regions 111 and the second regions 112 with higher accuracy in the first embodiment. Therefore, the carrier concentration distribution that can effectively alleviate the concentration of an electric field on the edges of the source region and/or the drain region abutting the gate electrode 130 can be formed more easily and more accurately, and thereby the more highly reliable TFT 10 is realized.

Further, as described above, according to shapes of the gate electrode 130 and the sidewall 151, the boundary of the channel region and the first regions 111 and the boundary of the first regions 111 and the second regions 112 are demarcated through so-called self-alignment in the first embodiment. In other words, the first regions 111 and the second regions 112 are formed to the edges of the gate electrode 130 and the sidewall 151. Thus, the first regions 111 are reliably formed in the edges of the source region and/or the drain region abutting the gate electrode 130 in which the concentration of an electric field easily occurs, and accordingly the concentration of an electric field can be suppressed more effectively. In addition, since a length of the first regions 111 in the channel direction remaining in the region immediately below the sidewall 151 is defined by a thickness of the sidewall 151 in the channel direction, the length of the first regions 111 in the channel region can be decided with higher accuracy.

Here, the TFT 10 is formed over a substrate, for example, a plastic substrate or the like composed of a resin-based material as described above. When a substrate that is made of a resin-based material is used as the substrate, it is difficult to perform a process in which a high temperature is exerted when denaturalization of the resin-based material is considered. On the other hand, according to the first embodiment, oxidation reduction between the oxide semiconductor layer 110 and the first reduction reaction film 140 and the second reduction reaction film 160 is performed through heat treatment of a relatively low temperature of about, for example, 100 to 300 degrees Celsius. Thus, even when the substrate over which the TFT 10 is formed is made of a material having relatively low heat resistance such as a resin-based material, the carrier concentration inside the oxide semiconductor layer 110 can be adjusted.

In addition, in the first embodiment, each of the processes of stacking of the first reduction reaction film 140 and the second reduction reaction film 160, heating for accelerating an oxidation-reduction reaction, and removal of the first reaction product 141 and the second reaction product 161 performed according to necessity can be executed through processes which are normally used in general TFT manufacturing processes, for example, sputtering, vapor deposition, etching, annealing, and the like. In that manner, the carrier concentration inside the oxide semiconductor layer 110 can be adjusted with high accuracy without using a special process, and thus manufacturing cost can be suppressed to be lower.

Note that, in above description, the case in which silicon is used as the material of the first reduction reaction film 140 and aluminum is used as the material of the second reduction reaction film 160 has been described, however, the first embodiment is not limited thereto. Materials of the first reduction reaction film 140 and the second reduction reaction film 160 may be appropriately selected from various kinds of metal materials described above. For example, as another combination of materials of the first reduction reaction film 140 and the second reduction reaction film 160 in which the second reduction reaction film 160 has a higher reduction property than the first reduction reaction film 140, a combination of hafnium used as a material of the first reduction reaction film 140 and magnesium used as a material of the second reduction reaction film 160 is exemplified.

### 1-3. Modified Examples

Next, several modified examples of the first embodiment described above will be described. Note that, when possible, the configurations relating to each of the modified examples to be described below may be applied to the second, third, and fourth embodiments to be described later.

### 1-3-1. Modified Example in which a First Reduction Reaction Film and a Second Reduction Reaction Film are Formed of the Same Material

In the first embodiment described above, the case in which the first reduction reaction film 140 and the second reduction reaction film 160 are formed of different materials has been described. The first embodiment, however, is not limited thereto. The first reduction reaction film 140 and the second reduction reaction film 160 may be formed of the same material in the first embodiment.

As described above, the first regions 111 are regions formed when the oxide semiconductor layer 110 is reduced by the first reduction reaction film 140. On the other hand, the second regions 112 are regions formed when, after the oxide semiconductor layer 110 is reduced by the first reduction reaction film 140, the oxide semiconductor layer 110 is further reduced by the second reduction reaction film 160. Thus, even when the first reduction reaction film 140 and the second reduction reaction film 160 are formed of the same material, it is possible to adjust the carrier concentration of the second regions 112 in which reduction reactions are repeated to be higher than the carrier concentration of the first regions 111.

In the heat treatment performed to form the second regions 112, however, it is necessary to induce another reduction reaction on the region in which the first regions 111 have already been formed as described above. Thus, when the first reduction reaction film 140 and the second reduction reaction film 160 are formed of the same material, there is a possibility it being difficult for the reduction reaction of the oxide semiconductor layer 110 performed to form the second regions 112 to progress. Therefore, in the present modified example, conditions for forming the second regions 112 may be appropriately adjusted so as to further promote the reduction reaction of the oxide semiconductor layer 110. In order to further promote the reduction reaction of the oxide semiconductor layer 110, processes of, for example, stacking the second reduction reaction film 160 thicker, setting a higher temperature and a longer time for conditions of the heat treatment, and the like are considered.

### 1-3-2. Modified Example in which a Sidewall is not Provided

In the first embodiment described above, after the reduction of the oxide semiconductor layer 110 by the first reduction reaction film 140 is performed, the sidewall 151 is formed, and then further reduction of the oxide semiconductor layer 110 by the second reduction reaction film 160 is performed. Through these steps, the first regions 111 remain in the region immediately below the sidewall 151, and thus the carrier concentration of the region remains lower than that of the second regions 112 and accordingly the carrier concentration distribution in which the carrier concentration decreases from the second regions 112 toward the channel region in stages can be realized. The first embodiment, however, is not limited thereto. In order to realize the above-described carrier concentration distribution in the first embodiment, the second regions 112 may be formed farther from the channel region than the first regions 111, and the sidewall 151 may not necessarily be formed.

When the sidewall 151 is not provided, in order to form the second regions 112 farther from the channel region than the first regions 111, oxidation-reduction between the second reduction reaction film 160 and the oxide semiconductor layer 110 may be performed in the state in which the second reduction reaction film 160 is not stacked in a region within a predetermined distance from the edges of the first regions 111 on the channel region side. As a method for realizing the stacking state of the second reduction reaction film 160, for example, performing a step in which, after the second reduction reaction film 160 is stacked over the oxide semiconductor layer 110 and the gate electrode 130, selective etching is performed using a mask, and thereby the region of the second reduction reaction film 160 within the predetermined distance from the edges of the first regions 111 on the channel region side is removed is considered.

In this manner, even when the sidewall 151 is not provided, by appropriately adjusting a region in which the oxide semiconductor layer 110 can be reduced by the second reduction reaction film 160 by, for example, processing the shape of the second reduction reaction film 160, the region in which the second regions 112 are formed can be controlled. Thus, even when the sidewall 151 is not provided, desired carrier concentration distribution in which, for example, the carrier concentration decreases from the second regions 112 toward the channel region in stages can be realized in the oxide semiconductor layer 110.

### 2. Second Embodiment

### 2-1. Structure and Manufacturing Method of a Semiconductor Device

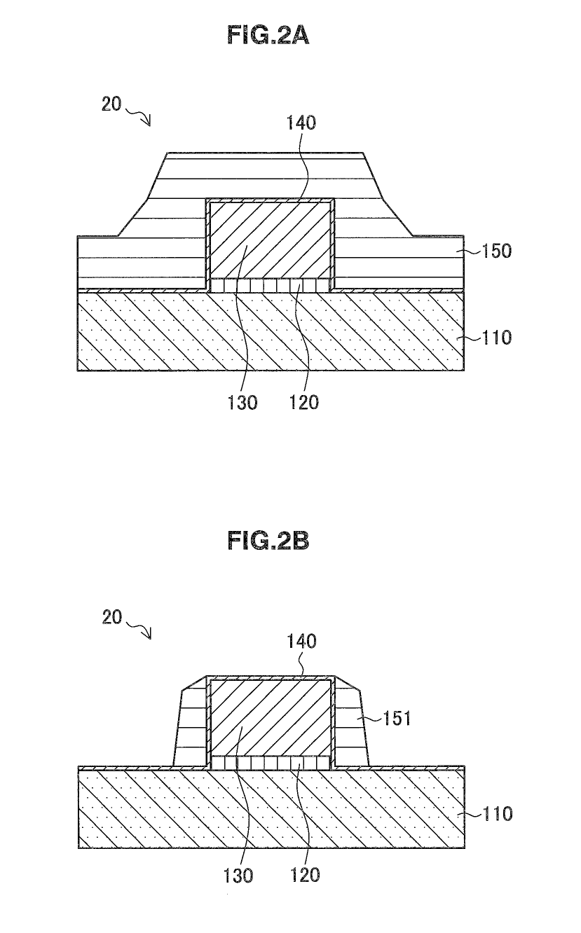

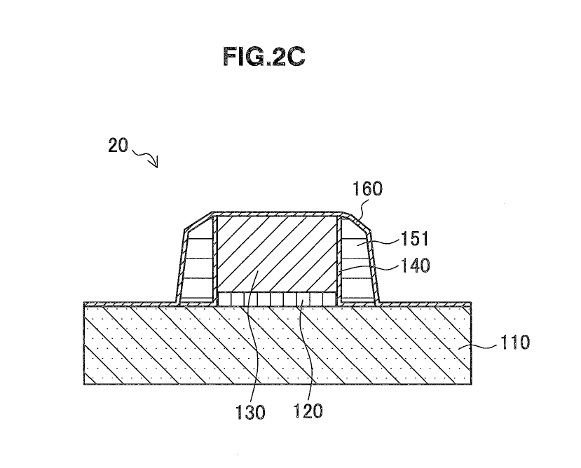

Next, a structure and a manufacturing method of a semiconductor device according to the second embodiment of the present disclosure will be described with reference to FIGS. 2A to 2C. FIGS. 2A to 2C are cross-sectional diagrams showing an example of the manufacturing method of the semiconductor device according to the second embodiment of the present disclosure. FIGS. 2A to 2C schematically illustrate a cross-section of a TFT 20 that is the semiconductor device according to the second embodiment in a channel direction in order of steps of the manufacturing method of the semiconductor device, showing a process flow of the manufacturing method.

Note that some processes in the manufacturing method of the TFT 20 of the second embodiment of the present disclosure are in a different order from those of the first embodiment described above. Each layer and film relating to the manufacturing method of the TFT 20 shown in FIGS. 2A to 2C may be formed using the same materials and manufacturing methods as those to which the same reference numerals are given in the first embodiment. In description with respect to the second embodiment provided hereinbelow, differences from the first embodiment will be mainly described, and detailed description of overlapping matters with the first embodiment will be omitted.

In the second embodiment, the same processes as in the first embodiment from formation of the gate insulation film 120 and the gate electrode 130 over the oxide semiconductor layer 110 to further stacking the first reduction reaction film 140 thereon are performed. The processes correspond to those shown in FIGS. 1A to 1B described above.

In the first embodiment, the first regions 111 are formed by performing the heat treatment on the configuration shown in FIG. 1B, however, in the second embodiment, the insulation film 150 is stacked over the oxide semiconductor layer 110, the gate electrode 130, and the first reduction reaction film 140 in an isotropic manner before heat treatment is performed as shown in FIG. 2A. Next, the insulation film 150 is selectively removed using anisotropic etching, for example, a dry etching method, or the like and thereby the sidewall 151 is formed along the side surface portion of the gate electrode 130 as shown in FIG. 2B.

Next, the second reduction reaction film 160 is stacked over the oxide semiconductor layer 110, the gate electrode 130, and the sidewall 151 as shown in FIG. 2C. Note that, before the second reduction reaction film 160 is stacked, the first reduction reaction film 140 that has been exposed at least on a surface of the oxide semiconductor layer 110 may be removed using, for example, an etching method or the like as shown in FIG. 2C.

Next, heat treatment is performed on the configuration shown in FIG. 2. Through the heat treatment, an oxidation-reduction reaction between the first reduction reaction film 140 and the oxide semiconductor layer 110 is promoted in the region immediately below the sidewall 151, and accordingly, the first regions 111 having a carrier concentration higher than that of other regions are formed inside the oxide semiconductor layer 110. In addition, also through the heat treatment, an oxidation-reduction reaction between the second reduction reaction film 160 and the oxide semiconductor layer 110 is promoted in the region other than the regions immediately below the gate electrode 130 and immediately below the sidewall 151, and accordingly, the second regions 112 having a carrier concentration higher than that of other regions are formed in the oxide semiconductor layer 110. In addition, as a result of the occurrence of the oxidation reactions, the first reduction reaction film 140 and the second reduction reaction film 160 change into the first reaction product 141 and the second reaction product 161 respectively. The TFT 20 after the heat treatment has the same configuration as that of the TFT 10 shown in, for example, FIG. 1G. As a source electrode for giving predetermined electric potential to the source region and a drain electrode for giving predetermined electric potential to the drain region in the respective second regions 112 positioned with the gate electrode 130 interleaved therebetween are formed in the configuration, the TFT 20 according to the second embodiment is completed.

Here, as in the first embodiment, for example, a material having a higher reaction property in a reduction reaction than that of the first reduction reaction film 140 is selected as a material of the second reduction reaction film 160. Thus, also in the second embodiment, the carrier concentration of the second regions 112 becomes higher than that of the first regions 111 in the oxide semiconductor layer 110, and thus the carrier concentration distribution in which the carrier concentration decreases from the second regions 112 toward the channel region in stages. Therefore, as in the first embodiment, the more highly reliable TFT 20 can be realized.

Note that, even when the second reduction reaction film 160 is stacked with the first reduction reaction film 140 remaining on the surface of the oxide semiconductor layer 110 in the region other than the regions immediately below the gate electrode 130 and immediately below the sidewall 151, the oxidation-reduction reactions of the oxide semiconductor layer 110 with both the first reduction reaction film 140 and the second reduction reaction film 160 are promoted in the region by appropriately adjusting the materials and the thicknesses of the first reduction reaction film 140 and the second reduction reaction film 160, conditions of the heat treatment, and the like, and thereby the second regions 112 can be formed. The carrier concentration of the second regions 112 formed as above is obtained by combining the carrier concentration caused by the reduction reaction of the first reduction reaction film 140 and the carrier concentration caused by the reduction reaction of the second reduction reaction film 160, and thus the carrier concentration of the second regions can be higher than that of the first regions 111. Therefore, the carrier concentration distribution in which the carrier concentration decreases from the second regions 112 toward the channel region in stages inside the oxide semiconductor layer 110 can be realized likewise, and thereby the more highly reliable TFT 20 can be realized.

Hereinabove, the structure and the manufacturing method of the semiconductor device according to the second embodiment of the present disclosure have been described with reference to FIGS. 2A to 2C. As described above, in the second embodiment, by performing the heat treatment after both of the first reduction reaction film 140 and the second reduction reaction film 160 are stacked, the step of reducing the oxide semiconductor layer 110 using the first reduction reaction film 140 and thereby forming the first regions 111 and the step of reducing the oxide semiconductor layer 110 using the second reduction reaction film 160 and thereby forming the second regions 112 are performed at the same time. Therefore, the number of steps can be decreased in comparison to the first embodiment, and accordingly manufacturing costs can be reduced.

### 3. Third Embodiment

### 3-1. Structure and Manufacturing Method of a Semiconductor Device

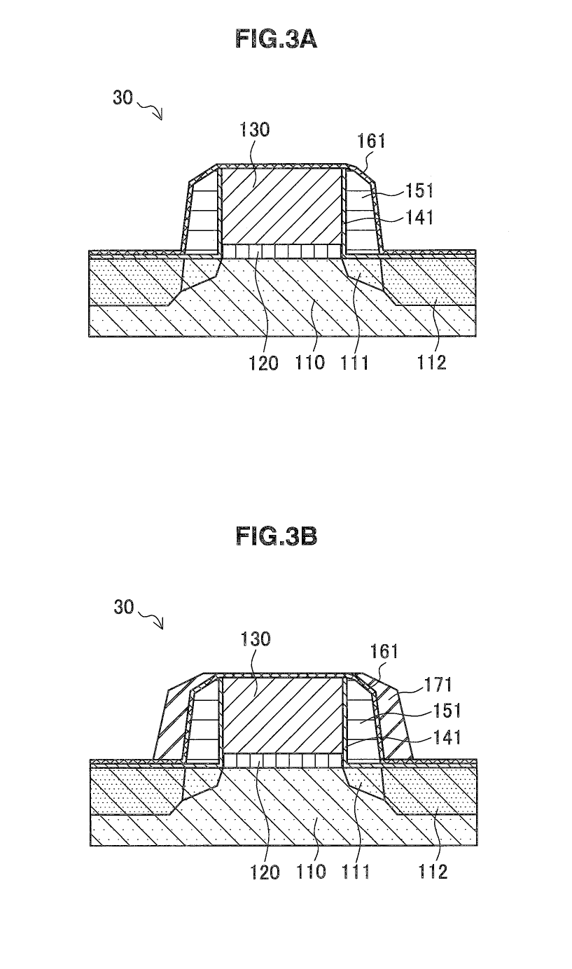

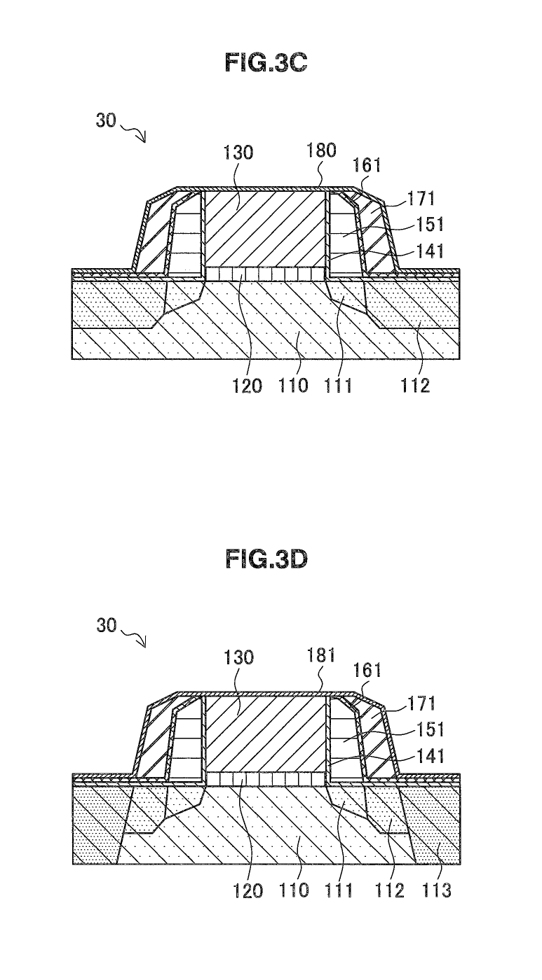

Next, a structure and a manufacturing method of a semiconductor device according to the third embodiment of the present disclosure will be described with reference to FIGS. 3A to 3C. FIGS. 3A to 3C are cross-sectional diagrams showing an example of the manufacturing method of the semiconductor device according to the third embodiment of the present disclosure. FIGS. 3A to 3C schematically illustrate a cross-section of a TFT 30 that is the semiconductor device according to the third embodiment in a channel direction in order of steps of the manufacturing method of the semiconductor device, showing a process flow of the manufacturing method.

Note that the processes of the third embodiment of the present disclosure correspond to the processes with which some other processes are added to the configuration of the first embodiment described above shown in FIG. 1G. Each layer and film relating to the manufacturing method of the TFT 30 shown in FIGS. 3A to 3D may be formed using the same materials and manufacturing methods as those to which the same reference numerals are given in the first embodiment. In description with respect to the third embodiment provided hereinbelow, differences from the first embodiment will be mainly described, and detailed description of overlapping matters with the first embodiment will be omitted.

As described above, in the third embodiment, the configuration shown in FIG. 1G is formed, in other words, the same processes of forming the gate insulation film 120, the gate electrode 130, and the sidewall 151 over the oxide semiconductor layer 110 and forming the first regions 111 and the second regions 112 in the oxide semiconductor layer 110 as in the first embodiment are performed. FIG. 3A is a diagram corresponding to FIG. 1G of the first embodiment, showing a configuration of the TFT 30 after the series of processes is performed in the third embodiment. As shown in FIG. 3A, in the third embodiment, for example, the second regions 112 can be formed in a region shallower from the surface of the oxide semiconductor layer 110 than in the first embodiment. Control of a depth at which the second regions 112 are formed as above can be performed using, for example, the material or the thickness of the second reduction reaction film 160, conditions of the heat treatment that induces an oxidation-reduction reaction to form the second regions 112, or the like.

Herein, the case in which, before the second reduction reaction film 160 is stacked, the first reaction product 141 exposed at least on the surface of the oxide semiconductor layer 110 is removed through, for example, an etching method or the like has been described in the first embodiment above. On the other hand, FIG. 3A illustrates a configuration in which the second reduction reaction film 160 is stacked without removing the first reaction product 141 exposed on the surface of the oxide semiconductor layer 110 and then the second regions 112 are formed as an example of the manufacturing method of the TFT 30. As illustrated in FIG. 3A, when the second reduction reaction film 160 is stacked without removing the first reaction product 141, the first reaction product 114 is stacked in the region in which the first regions 111 are formed on the surface of the oxide semiconductor layer 110, and the first reaction product 141 and the second reaction product 161 are stacked in the region in which the second regions 112 are formed on the surface of the oxide semiconductor layer 110, and thus a level difference is generated on the surface of the oxide semiconductor layer 110. As described in [1-1. Structure and manufacturing method of a semiconductor device] described above, such a level difference is normally considered to have an extremely small influence on an electrical characteristic of the TFT 30; however, a process of reducing the level difference may be appropriately performed if necessary. In addition, also in the third embodiment, the second reduction reaction film 160 may of course be stacked after the first reaction product 141 exposed on the surface of the oxide semiconductor layer 110 is removed, and then the second regions 112 may be formed as in the first embodiment.

In the third embodiment, another sidewall 171 is next formed in the side surface portion of the sidewall 151 as shown in FIG. 3B. Hereinbelow, the sidewall 151 and the sidewall 171 are also referred to as the first sidewall 151 and the second sidewall 171 for the sake of convenience. The sidewall 171 can be formed such that a predetermined insulation film is stacked over the oxide semiconductor layer 110, the gate electrode 130, the sidewall 151, the first reaction product 141, and the second reaction product 161 in an isotropic manner and then the insulation film is selectively removed using anisotropic etching, for example, the dry etching method, or the like, like the sidewall 151.

Next, as shown in FIG. 3C, a third reduction reaction film 180 is stacked over the oxide semiconductor layer 110, the gate electrode 130, the sidewall 151, the first reaction product 141, the second reaction product 161, and the sidewall 171. The third reduction reaction film 180 can be formed of the same material as any of those exemplified in [1-1. Structure and manufacturing method of a semiconductor device] above as materials that the first reduction reaction film 140 can be formed of. The third reduction reaction film 180 has the function of causing an oxidation-reduction reaction with the oxide semiconductor layer 110 through heat treatment and thereby reducing the oxide semiconductor layer 110, like the first reduction reaction film 140 and the second reduction reaction film 160. Note that, in description below, the reaction in which the oxide semiconductor layer 110 is reduced by the third reduction reaction film 180 will also be referred to as a third reduction reaction.

Here, when the first reduction reaction film 140, the second reduction reaction film 160, and the third reduction reaction film 180 are formed of different materials from each other, it is preferable to form the second reduction reaction film 160 using a material having a higher reduction property than the material of the first reduction reaction film 140, and it is preferable to form the third reduction reaction film 180 using a material having a higher reduction property than the material of the second reduction reaction film 160. As a combination of materials of the first reduction reaction film 140, the second reduction reaction film 160, and the third reduction reaction film 180 that satisfies the above condition, for example, tungsten can be used as the material of the first reduction reaction film 140, hafnium as the material of the second reduction reaction film 160, and aluminum as the material of the third reduction reaction film 180.

The third embodiment, however, is not limited to the above, and the first reduction reaction film 140, the second reduction reaction film 160, and the third reduction reaction film 180 may be formed of the same material. Even when the first reduction reaction film 140, the second reduction reaction film 160, and the third reduction reaction film 180 are formed of the same material, conditions for forming the second regions 112 and third regions 113 to be described later may be appropriately adjusted as described in (1-3-1. Modified example in which a first reduction reaction film and a second reduction reaction film are formed of the same material) above so that the reduction reaction of the oxide semiconductor layer 110 by the second reduction reaction film 160 and the reduction reaction of the oxide semiconductor layer 110 by the third reduction reaction film 180 are further promoted. In order to further promote the reduction reactions of the oxide semiconductor layer 110, for example, processes of stacking the second reduction reaction film 160 and the third reduction reaction film 180 thicker, setting a higher temperature and a longer time for the conditions of the heat treatment, and the like are considered.

Note that, in the example shown in FIG. 3C, the case in which the third reduction reaction film 180 is stacked without removing the second reaction product 161 exposed on the surface of the oxide semiconductor layer 110 is illustrated, however, the third embodiment is not limited thereto. Similarly to the case in which the second reduction reaction film 160 is stacked in the first embodiment, the second reaction product 161 exposed at least on the surface of the oxide semiconductor layer 110 may be removed using, for example, an etching method or the like before the third reduction reaction film 180 is stacked.

Next, heat treatment is performed on the configuration shown in FIG. 3C at a heating temperature of, for example, about 100 to 300 degrees Celsius. Through the heat treatment, an oxidation-reduction reaction occurs between the oxide semiconductor layer 110 and the third reduction reaction film 180.

FIG. 3D shows a structure of the TFT 30 after the heat treatment. As a result of the occurrence of the reduction reaction, the region of the oxide semiconductor layer 110 abutting the third reduction reaction film 180 via the first reaction product 141 and the second reaction product 161 (to be specific, the region in which the gate electrode 130, the sidewall 151, and the sidewall 171 are not formed), the third regions 113 that are regions having an increased carrier concentration than other regions are formed. As shown in FIG. 3C, the third reduction reaction film 180 is stacked over the oxide semiconductor layer 110 such that a part thereof overlaps the region in which the second regions 112 are formed. Since the reduction reaction of the region of the oxide semiconductor layer 110 immediately below the third reduction reaction film 180 is promoted by the heat treatment, the third regions 113 are regions having a carrier concentration higher than that of the second regions 112 in which the increase amount of the carrier concentration caused by the first reduction reaction film 140, the increase amount of the carrier concentration caused by the second reduction reaction film 160, and the increase amount of the carrier concentration caused by the third reduction reaction film 180 are combined.

In the heat treatment to form the third regions 113, it is necessary to induce another reduction reaction on the regions in which the second regions 112 have already been formed, however, as a material of the third reduction reaction film 180, a material having a higher reduction property than those of the first reduction reaction film 140 and the second reduction reaction film 160 can be suitably selected as described above, and accordingly the reduction reaction relating to the heat treatment is promoted more easily and the third regions 113 are formed more easily. Note that, in the example shown in FIG. 3C, the configuration of the TFT 30 in which the third reduction reaction film 180 is stacked with the first reaction product 141 and/or the second reaction product 161 remaining on the surface of the oxide semiconductor layer 110 is illustrated, however, also in such a case, the oxidation-reduction reaction between the oxide semiconductor layer 110 and the third reduction reaction film 180 can be promoted with the first reaction product 141 and/or the second reaction product 161 therebetween by appropriately adjusting the material and thickness of the third reduction reaction film 180, conditions of the heat treatment, and the like, and thereby the third regions 113 can be formed.

In addition, as a result of the occurrence of the oxidation reaction, the third reduction reaction film 180 changes into a third reaction product 181. The third reaction product 181 can be an oxide of the material composing the third reduction reaction film 180. For example, since the third reduction reaction film 180 is formed of aluminum in the example described above, the third reaction product 181 can be an aluminum oxide (Al₂O₃). Note that the example shown in FIG. 3D illustrates that the entire third reduction reaction film 180 changes into the third reaction product 181 since the third reduction reaction film 180 is formed as a relatively thin film, but the third reaction product 181 may actually be generated in a region of the third reduction reaction film 180 at a predetermined depth from the location of the oxide semiconductor layer 110, the gate insulation film 120, and the gate electrode 130.

In the TFT 30, the third regions 113 are used as a source region and a drain region. A source electrode (not illustrated) for giving predetermined electric potential to the source region and a drain electrode (not illustrated) for giving predetermined electric potential to the drain region are formed in the respective third regions 113 having the gate electrode 130 therebetween, and thereby the TFT 30 according to the third embodiment is completed.

Here, as described above, the gate insulation film 120, the gate electrode 130, the sidewall 151 and the sidewall 171 are formed over the oxide semiconductor layer 110, and then the third reduction reaction film 180 is stacked thereon in the third embodiment. Thus, the third reduction reaction film 180 hardly causes an oxidation-reduction reaction with the oxide semiconductor layer 110 in the region immediately below the gate electrode 130, the sidewall 151 and the sidewall 171, and reduces the oxide semiconductor layer 110 in other regions. Accordingly, the third regions 113 in which the carrier concentration has increased are generated mainly in the region in which the gate electrode 130, the sidewall 151 and the sidewall 171 are not formed, and are hardly generated in other regions.

In addition, since the first reduction reaction film 140 is stacked so as to hardly cause the oxidation-reduction reaction with the oxide semiconductor layer 110 in the channel region immediately below the gate electrode 130 and to reduce the oxide semiconductor layer 110 in the other region, the first regions 111 are generated mainly in the region other than the channel region as shown in FIG. 1C. Further, since the second reduction reaction film 160 is stacked so as to hardly cause the oxidation-reduction reaction with the oxide semiconductor layer 110 in the region immediately below the gate electrode 130 and the sidewall 151 and to reduce the oxide semiconductor layer 110 in the other region, the second regions 112 are generated mainly in the region other than the region immediately below the gate electrode 130 and the sidewall 151 as shown in FIG. 1F.

Based on the above, in the third embodiment, the carrier concentration inside the oxide semiconductor layer 110 of the TFT 30 has the distribution in which the concentration is lowest in the channel region immediately below the gate electrode 130, and the carrier concentration gradually increases toward the first regions 111 formed in the region immediately below the sidewall 151, the second regions 112 formed in the region immediately below the sidewall 171, and the third regions 113 formed in the other region. Thus, by using the third regions 113 as a source region and a drain region, a channel is formed such that the carrier concentration decreases from the source region and the drain region toward the channel region in stages, and concentration of an electric field on the edges of the source region and/or the drain region abutting the gate electrode 130 is alleviated. Therefore, according to the third embodiment, the TFT 30 having higher reliability can be formed.

In addition, the third reduction reaction film 180 is stacked after the sidewall 171 is formed in the third embodiment, and a region of the oxide semiconductor layer 110 reduced by the third reduction reaction film 180 is decided according to a formation position of the sidewall 171. That is to say, according to a shape of the sidewall 171, the boundaries of the second regions 112 and the third regions 113 are demarcated through so-called self-alignment. In this manner, since formation positions of the third regions 113 can be decided according to a formation position of the sidewall 171 in the third embodiment, positions in which the carrier concentration changes in stages (the boundaries of the second regions 112 and the third regions 113) can be decided more accurately, and thus the more highly reliable TFT 30 is realized.

In the third embodiment, however, the third regions 113 may be formed farther from the channel region than the second regions 112, the carrier concentration distribution in which the carrier concentration decreases from the third regions 113 toward the channel region in stages may be realized, and the sidewall 171 may not necessarily be provided. As in the modified example described in (1-3-2. Modified example in which a sidewall is not provided) above, for example, the regions in which the third regions 113 may be controlled by appropriately adjusting the region of the oxide semiconductor layer 110 that can be reduced by the third reduction reaction film 180 by processing the stacked third reduction reaction film 180 in a predetermined pattern. For example, by removing a region of the third reduction reaction film 180 within a predetermined distance from the edges of the second regions 112 on the channel region side through selective etching using a mask after the third reduction reaction film 180 is stacked over the oxide semiconductor layer 110, the gate electrode 130, and the sidewall 151, the desired carrier concentration distribution in which the carrier concentration decreases from the third regions 113 toward the channel region in stages as described above can be realized.

In addition, like the first regions 111 and the second regions 112, the carrier concentration and formation depth of the third regions 113 can be decided at least based on, for example, the material and thickness of the third reduction reaction film 180, and the conditions of the heat treatment (the heating time, the heating temperature, and the like) at the time of the oxidation-reduction reaction. The parameters such as the stacking position and thickness of the third reduction reaction film 180, and the conditions of the heat treatment at the time of the oxidation-reduction reaction can be relatively easily controlled with high accuracy in existing processes, and thus, in the third embodiment, the formation position, the formation depth and/or the carrier concentration of the third regions 113 can be controlled with higher accuracy. Accordingly, the carrier concentration distribution that can alleviate the concentration of an electric field on the edges of the source region and/or the drain region abutting the gate electrode 130 can be formed more easily with higher accuracy, and thereby the more highly reliable TFT 30 is realized.

### 4. Second Embodiment

### 4-1. Structure and manufacturing method of a semiconductor device

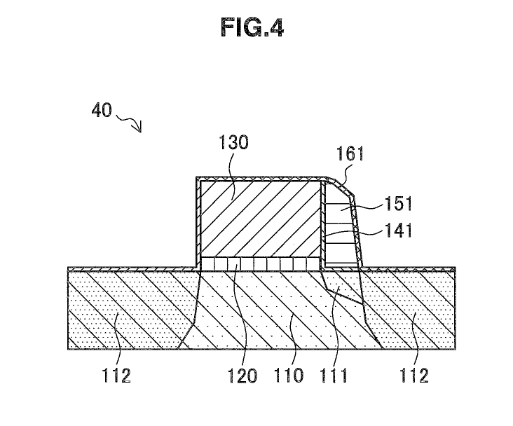

Next, a structure and a manufacturing method of a semiconductor device according to the fourth embodiment of the present disclosure will be described with reference to FIG. 4. FIG. 4 is a cross-sectional diagram showing an example of the manufacturing method of the semiconductor device according to the fourth embodiment of the present disclosure. FIG. 4 schematically illustrates a cross-section of a TFT 40 that is the semiconductor device according to the fourth embodiment in a channel direction in order of steps of the manufacturing method of the semiconductor device, showing a process flow of the manufacturing method.

Note that the processes of the fourth embodiment of the present disclosure correspond to the processes which a part of configuration of the TFT 10 are omitted from the first embodiment described above. Each layer and film relating to the manufacturing method of the TFT 40 shown in FIG. 4 may be formed using the same materials and manufacturing methods as those to which the same reference numerals are given in the first embodiment. In description with respect to the fourth embodiment provided hereinbelow, differences from the first embodiment will be mainly described, and detailed description of overlapping matters with the first embodiment will be omitted.

In the fourth embodiment, the sidewall 151 is formed on only one side of the gate electrode 130 in the step of forming the sidewall 151 in the first embodiment (see FIG. 1E). Such a structure of the sidewall 151 can be formed such that, for example, after the insulation film 150 is stacked over the oxide semiconductor layer 110 and the gate electrode 130 in an isotropic manner as shown in FIG. 1D, the insulation film 150 is selectively removed using anisotropic etching such as the dry etching method so that only the sidewall 151 of one side is left.

In the fourth embodiment, the second reduction reaction film 160 is stacked over the configuration in which the sidewall 151 is formed only on one side of the gate electrode 130, and then heat treatment is performed at a heating temperature of, for example, about 100 to 300 degrees Celsius. Note that, as in the first embodiment, the first reaction product 141 exposed at least on the surface of the oxide semiconductor layer 110 may be removed using, for example, an etching method or the like before the second reduction reaction film 160 is stacked.

FIG. 4 shows a structure of the TFT 40 after the heat treatment. Same as the first embodiment, as a result of the occurrence of the reduction reaction, the second regions 112 that are regions in which a carrier concentration has increased more than other regions are formed in the region in which the second reduction reaction film 160 is in contact with the oxide semiconductor layer 110 (to be specific, the region in which the gate electrode 130 and the sidewall 151 are not formed). In addition, as a result of the occurrence of the oxidation reaction, the second reduction reaction film 160 changes into the second reaction product 161.

As described above, since the sidewall 151 is formed only on one side of the gate electrode 130 in the fourth embodiment, the first region 111 and the second regions 112 are formed in different regions from those in the first embodiment. To be specific, the first region 111 is formed in the region immediately below the sidewall 151 on the side on which the sidewall 151 is formed as in the first embodiment, and one second region 112 is formed in the outer regions from the edge of the sidewall 151 including the edges, and thereby phased carrier concentration distribution can be formed. On the other hand, the second reduction reaction film 160 is stacked on the side on which the sidewall 151 is not formed to the region of the edge of the oxide semiconductor layer 110 abutting the gate electrode 130, and accordingly the other second region 112 is formed in the outer region from the edge of the gate electrode 130 including the edge. As described above, in the fourth embodiment, different carrier concentration distribution is formed inside the oxide semiconductor layer 110 on one side and the other side of the gate electrode 130 in the channel direction, i.e., in the source region and the drain region.

When, for example, particularly excessive concentration of an electric field can occur in any of the source region and the drain region according to a property of the TFT 40, the sidewall 151 may be formed only on the side on which the occurrence of the excessive concentration of an electric field is a concern to allow the second reduction reaction film 160 to reduce the oxide semiconductor layer 110. Accordingly, on the side on which the sidewall 151 is formed, i.e., on which the occurrence of excessive concentration of an electric field is a concern, concentration distribution in which the carrier concentration decreases from the second region 112 toward the channel region in stages is formed, and thereby concentration of an electric field on an edge of the source region or the drain region abutting the gate electrode 130 is alleviated. In the fourth embodiment, the carrier concentration distribution of the oxide semiconductor layer 110 is selectively formed only in a necessary portion, and accordingly a change in other properties of the TFT 40 can be suppressed, and concentration of an electric field can be alleviated. Therefore, reliability of the TFT 40 can be further improved.

So far, the structure and the manufacturing method of the semiconductor device according to the fourth embodiment of the present disclosure have been described with reference to FIG. 4.

### 5. Application Examples

Next, application examples of the TFTs 10, 20, 30, and 40 according to the first, second, third, and fourth embodiments described above to various equipment, devices, and electronic apparatuses will be described. Note that, in description with regard to the application examples below, cases in which the TFT 10 according to the first embodiment or a TFT 80 according to a modified example of the first, second, third, and fourth embodiments to be described later are mounted in various equipment, devices, and electronic apparatuses will be exemplified, however, the TFTs 20, 30, and 40 according to the second, third, and fourth embodiments can also be applied to various equipment, devices, and electronic apparatuses.

### 5-1. Application to an Organic EL Display Device

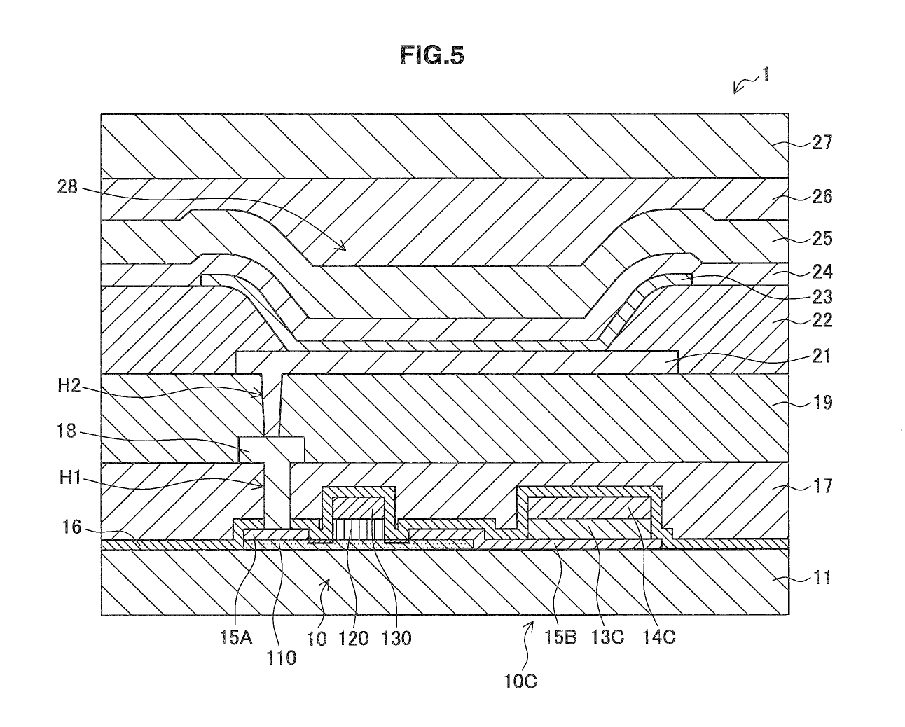

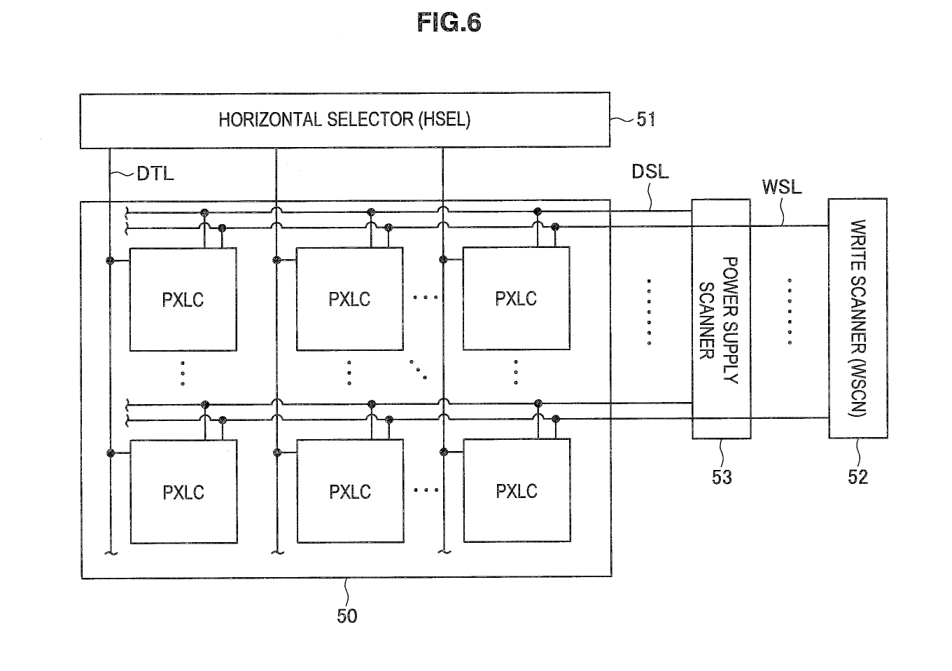

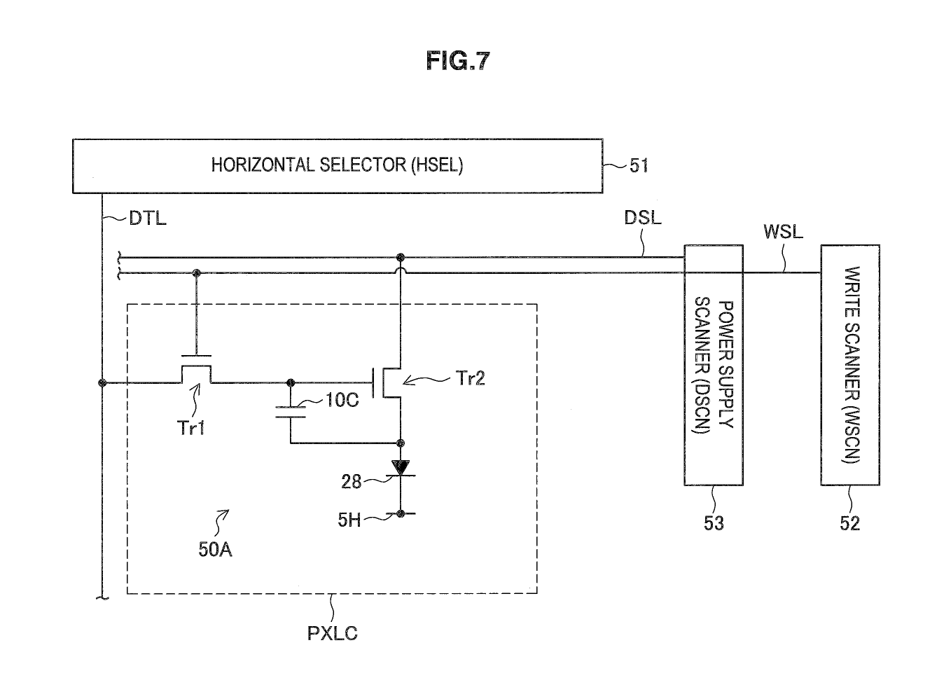

The TFT 10 according to the first embodiment can be suitably applied as a transistor for driving pixels in an organic electro-luminescence (EL) display device. Here, the organic EL display device refers to a display device of which light emitting elements of each pixel of a display screen are constituted by organic EL elements, and which performs predetermined display on the display screen by selectively driving the organic EL elements using a transistor that is a driving element. A configuration example in which the TFT 10 according to the first embodiment is applied to a pixel driving element of an organic EL display device will be described with reference to FIGS. 5 to 7. FIG. 5 is a cross-sectional diagram of an organic EL display device to which the TFT 10 according to the first embodiment is applied showing a schematic configuration of a region corresponding to one pixel. FIG. 6 is a schematic diagram of a circuit configuration of the organic EL display device to which the TFT 10 according to the first embodiment is applied. FIG. 7 is a schematic diagram showing a configuration of a periphery circuit of one pixel of the circuit configuration shown in FIG. 6 in detail.

Referring to FIG. 5, the organic EL display device 1 is an active-matrix organic EL display device, and includes a plurality of TFTs 10 over a substrate 11 and organic EL elements 28 driven by the TFTs 10. FIG. 5 shows a cross-sectional structure of a region that includes one TFT 10 and organic EL element 28 as a region corresponding to one pixel of the organic EL display device 1.

Since the configuration of the TFT 10 has already been described in <1. First embodiment> above, detailed description thereof will be omitted. Etching protection films 15A and 15B are respectively provided in regions corresponding to the source region and the drain region on the oxide semiconductor layer 110 of the TFT 10. Further, an oxidized film 16 is provided so as to cover the etching protection films 15A and 15B and the gate electrode 130, and an inter-layer insulation film 17 is further provided on the oxidized film 16. A pair of source or drain electrodes 18 (one of which is not illustrated) are electrically connected to an oxide semiconductor layer 110 via connection holes H1 (one of which is not illustrated) provided to penetrate the inter-layer insulation film 17 and the oxidized film 16. The regions of the oxide semiconductor layer 110 connected to the source or drain electrodes 18 are, for example, the regions corresponding to the second regions 112 shown in FIG. 1G. Note that, in order to avoid complicating the drawing, out of the configuration of the TFT 10, only the oxide semiconductor layer 110, the gate insulation film 120, and the gate electrode 130 are illustrated in FIG. 5, and other configurations are not illustrated.

The organic EL display device 1 has a retention capacitor element 10C that shares the TFT 10 with one of the pair of etching protection films 15A and 15B (the etching protection film 15B in the example shown in FIG. 5). The retention capacitor element 10C is a capacitor element for retaining electric charge corresponding to a voltage applied to the organic EL element 28 when the pixel is driven. The organic EL element 28 is provided over the TFT 10 and the retention capacitor element 10C with a flattening film 19 therebetween.

The substrate 11 is formed of a material such as quartz, glass, silicon, a resin (plastic) film, or the like. As a resin material, for example, polyethylene terephthalate (PET) or polyethylene naphthalate (PEN) can be used. Since, in the first embodiment, the heat treatment to form the first regions 111 and the second regions 112 can be performed at a relatively low temperature of about 100 to 300 degrees Celsius as described above, a relatively inexpensive resin film can be suitably used as the substrate 11. In addition, depending on objectives, a metal substrate formed of stainless steel (SUS) or the like may be used as the substrate 11.

The etching protection film 15A is a film for protecting the oxide semiconductor layer 110 from etching when the connection hole H1 is formed in the inter-layer insulation film 17 and the oxidized film 16. The etching protection film 15B is provided to face the etching protection film 15A having the gate electrode 130 therebetween and extend toward an outer side of the oxide semiconductor layer 110, and constitutes one electrode (the lower electrode in the illustrated example) of the retention capacitor element 10C. Like the etching protection film 15A, the etching protection film 15B is also a film for protecting the oxide semiconductor layer 110 from etching performed when a through hole (not illustrated) for connecting the source or drain electrode (not illustrated) paired with the source or drain electrode 18 to the oxide semiconductor layer 110 is formed. By providing the etching protection films 15A and 15B, damage to the oxide semiconductor layer 110 inflicted during manufacturing steps can be prevented, and an electrical characteristic of the TFT 10 can be enhanced. Note that at least a part of the etching protection films 15A and 15B may be connected to the oxide semiconductor layer 110.

The second regions 112 of the oxide semiconductor layer 110 shown in FIG. 1G can be electrically connected to the source or drain electrode 18 via the etching protection films 15A and 15B. The etching protection films 15A and 15B may be composed of a metal material having a different etching selectivity from the material composing the oxide semiconductor layer 110, for example, indium tin oxide (ITO), or aluminum including molybdenum or neodymium. As the etching protection films 15A and 15B, a semiconductor material having decreased resistance, for example, silicon or germanium (Ge) including phosphorus (P), boron (B), or arsenic (As) as dopants can also be used. A thickness of the etching protection films 15A and 15B is, for example, about 100 nm.

The oxidized film 16 provided on the etching protection films 15A and 15B comes in contact with the oxide semiconductor layer 110 between the gate electrode 130 and the respective etching protection films 15A and 15B. In addition, the oxidized film 16 can also be provided to cover the retention capacitor element 10C. Here, the oxidized film 16 corresponds to the first reaction product 141 and/or the second reaction product 161 described above. In other words, the oxidized film 16 has a configuration of, for example, a silicon oxide or an aluminum oxide, or a configuration in which a silicon oxide and an aluminum oxide are stacked. The oxidized film 16 is a by-product generated when the first regions 111 and the second regions 112 are formed, and has a function of protecting the oxide semiconductor layer 110 from oxygen or moisture that can change the electrical characteristic of the TFT 10. Thus, by leaving the oxidized film 16 at least on a surface of the oxide semiconductor layer 110 when the TFT 10 is manufactured, the electrical characteristic of the TFT 10 can be stabilized more.

The inter-layer insulation film 17 is provided on the oxidized film 16, and covers both of the TFT 10 and the retention capacitor element 10C like the oxidized film 16. The inter-layer insulation film 17 is composed of an organic material, for example, an acryl resin, polyimide, or siloxane, or an inorganic material such as a silicon oxide, a silicon nitride, a silicon oxy-nitride, or an aluminum oxide. In addition, the inter-layer insulation film 17 may be formed by stacking the organic materials and the inorganic materials. The inter-layer insulation film 17 can be stacked to have a thickness of, for example, about 2 μm, however, when the inter-layer insulation film 17 contains an organic material, formation thereof with a thickness of about 2 μm can be easily performed. By stacking the inter-layer insulation film 17 relatively thickly at about 2 μm, level differences generated between the gate electrode 130 and the source region and the drain region can be sufficiently covered, and a high insulation property can be ensured.

The source or drain electrode 18 is connected to the etching protection films 15A and 15B through the connection hole H1 provided to penetrate the inter-layer insulation film 17 and the oxidized film 16. The source or drain electrode 18 can be formed of, for example, any of the various metal materials described above as a material of which the gate electrode 130 can be formed. The source or drain electrode 18, however, is preferably formed of a low resistance metal material such as aluminum or copper. By forming the source or drain electrode 18 using such a low resistance metal material, pixels can be driven with little wiring delay.

The retention capacitor element 10C is configured by stacking the etching protection film 15B shared with the TFT 10, a capacitor insulation film 13C, and an upper electrode 14C in this order over the substrate 11. As described above, one electrode (lower electrode) of the retention capacitor element 10C is constituted by a part of the etching protection film 15B.

The capacitor insulation film 13C may be formed, for example, in the same step as the gate insulation film 120, and can be formed of the same material with the same thickness as the gate insulation film 120. In addition, the upper electrode 14C may be formed, for example, in the same step as the gate electrode 130, and can be formed of the same material with the same thickness as the gate electrode 130. The capacitor insulation film 13C and the gate insulation film 120, however, may be formed in different steps, and may be formed of different materials with different thicknesses. Likewise, the upper electrode 14C and the gate electrode 130 may be formed in different steps, and formed of different materials with different thicknesses.

The organic EL element 28 is provided on the flattening film 19. The organic EL element 28 is formed by stacking a first electrode 21, a pixel separation film 22, an organic layer 23, and a second electrode 24 on the flattening film 19 in this order. In addition, the top of the organic EL element 28 is sealed by an element protection layer 25. Further, a sealing substrate 27 is affixed to the top of the element protection layer 25 having an adhesive layer 26 that is formed of a heat-curable resin or a UV-curable resin therebetween. The display device 1 may be a bottom emission type in which light generated in the organic layer 23 is discharged from the substrate 11 side (bottom light-emission type), or may be a top emission type in which light is discharged from the sealing substrate 27 (top light-emission type).

The flattening film 19 is provided on the source or drain electrode 18 and the inter-layer insulation film 17 to cover the entire display region of the display device 1, and a partial region thereof has a connection hole H2 that is a through hole formed therein. The source or drain electrode 18 of the TFT 10 is electrically connected to the first electrode 21 of the organic EL element 28 through the connection hole H2. The flattening film 19 is formed of, for example, a polyimide or an acrylic resin.

The first electrode 21 is formed to be stacked on the flattening film 19 and to be embedded in the connection hole H2. The first electrode 21 functions as, for example, the anode of the organic EL element 28, and is provided for each pixel. When the display device 1 is the bottom emission type, the first electrode 21 is configured as a transparent conductive film, for example, a single-layered film composed of any of ITO, indium oxide zinc (IZO), indium zinc oxide (InZnO), or the like or a stacked film composed of two or more of these. On the other hand, when the display device 1 is the top emission type, the first electrode 21 is configured as, for example, a single-layered film composed of a reflective metal, for example, a single metal that includes at least one of aluminum, magnesium, calcium, sodium, and the like, or an alloy that includes at least one of these, or a multi-layered film in which the single metal or the alloy is stacked.

The pixel separation film 22 secures an insulation property between the first electrode 21 and the second electrode 24 and compartmentalizes the light emission region of each organic EL element 28. The plurality of organic EL elements 28 formed and arrayed over the substrate 11 are compartmentalized by the pixel separation film 22 in units of pixels so that, for example, each of the organic EL elements 28 is positioned in one pixel. The pixel separation film 22 is provided with an opening portion in a region corresponding to the light emission region of the organic EL element 28. The pixel separation film 22 is formed of a photosensitive resin, for example, a polyimide, an acrylic resin, a novolac-based resin, or the like.

The organic layer 23 is provided so as to cover the opening portion of the pixel separation film 22. The organic layer 23 includes an organic electroluminescent layer (organic EL layer), and emits light when a driving current is applied. The organic layer 23 has a configuration in which, for example, a hole injection layer, a hole transfer layer, an organic EL layer, and an electron transfer layer are stacked in this order from the substrate 11 (first electrode 21) side, and emits light when recombination of electrons and holes occurs in the organic EL layer. A material composing the organic EL layer may be a general low-molecular or high-molecular organic material, and is not particularly limited. Each of the organic EL elements 28 may include, for example, any of organic EL layers emitting specific monochromic light (for example, red, green or blue light), or each of the organic EL elements 28 may include an organic EL layer (in which, for example, red, green, and blue organic EL layers are stacked) which emits white light. The hole injection layer is for improving hole injection efficiency and preventing leakage, and the hole transfer layer is for improving hole transfer efficiency with respect to the organic EL layer. The layers other than the organic EL layer such as the hole injection layer, the hole transfer layer, and the electron transfer layer, however, are not indispensable constituent elements for the organic layer 23, and may be provided as necessary.

The second electrode 24 functions as, for example, the cathode of the organic EL element 28, and is formed of a metal conductive film. When the organic EL display device 1 is the bottom emission type, the second electrode 24 is configured as a single-layered film composed of a reflective metal, for example, a single metal that includes at least one of aluminum, magnesium, calcium, sodium, and the like, or an alloy that includes at least one of these, or a multi-layered film in which the single metal or the alloy is stacked. On the other hand, when the organic EL display device 1 is the top emission type, the second electrode 24 is formed of a transparent conductive film of ITO, IZO, or the like. The second electrode 24 is provided as, for example, a common electrode for the plurality of the organic EL elements 28 in the state in which the second electrode is insulated from the first electrode 21.

The element protection layer 25 may be composed of any material of an insulating material or a conductive material. As the insulating materials that can be used as the element protection layer 25, for example, amorphous silicon (a-Si), amorphous silicon carbide (a-SiC), amorphous silicon nitride (a-Si₁₋ₓNₓ), amorphous carbon (a-C), and the like are exemplified.

The sealing substrate 27 is provided to face the substrate 11 having the TFT 10, the retention capacitor element 10C, and the organic EL element 28. The sealing substrate 27 may be formed of, for example, the same material as the substrate 11. When the organic EL display device 1 is the top emission type, the sealing substrate 27 may be formed of a transparent material and a layer of a color filter, a light shielding film, or the like may be further provided on one side of the sealing substrate 27. In addition, when the organic EL display device 1 is the bottom emission type, the substrate 11 may be formed of a transparent material and a layer of a color filter, a light shielding film, or the like may be further provided on one side of the substrate 11.

So far, the schematic configuration of the pixel region of the organic EL display device 1 in which the TFT 10 according to the first embodiment is mounted has been described. Next, a circuit configuration relating to driving of each pixel of the organic EL display device 1 will be described with reference to FIGS. 6 and 7.

As shown in FIGS. 6 and 7, the organic EL display device 1 has a plurality of pixels PXLC, each of which includes the organic EL element 28 described above. The pixels PXLC are arranged in a display region 50 over the substrate 11 in, for example, a matrix shape. In the periphery of the display region 50, a horizontal selector (HSEL) 51 which is a signal line driving circuit, a write scanner (WSCN) 52 which is a scanning line driving circuit, and a power supply scanner 53 which is a power supply line driving circuit are provided.

In the display region 50, a plurality of signal lines DTL1 to DTLn (n is an integer) extend in the column direction, and a plurality of scanning lines WSL1 to WSLm (m is an integer) extend in the row direction. In addition, a plurality of power supply lines DSL also extend in the row direction. At each intersection of the signal lines DTL and the scanning lines DSL, each pixel PXLC (any one pixel corresponding to R, G, or B) is provided. Each signal line DTL is electrically connected to the horizontal selector 51, and a video signal is supplied to each pixel PXLC from the horizontal selector 51 through the signal line DTL. On the other hand, each scanning line WSL is electrically connected to the write scanner 52, and a scanning signal (selection pulse) is supplied to each pixel PXLC from the write scanner 52 through the scanning line WSL. In addition, each power supply line DSL is connected to the power supply scanner 53, and a power supply signal (control pulse) is supplied to each pixel PXLC from the power supply scanner 53 through the power supply line DSL.

FIG. 7 illustrates a specific circuit configuration example of one pixel PXLC. Each pixel PXLC has a pixel circuit 50A that includes the organic EL element 28. In the example illustrated, the pixel circuit 50A is an active-type driving circuit that has a sampling transistor Tr1, a driving transistor Tr2, the retention capacitor element 10C, and the organic EL element 28. Note that at least one of the sampling transistor Tr1 and the driving transistor Tr2 corresponds to the TFT 10 according to the first embodiment.

The gate of the sampling transistor Tr1 is connected to the scanning line WSL. In addition, one of the source and the drain of the sampling transistor Tr1 is connected to the signal line DTL, and the other thereof is connected to the gate of the driving transistor Tr2. The drain of the driving transistor Tr2 is connected to the power supply line DSL, and the source thereof is connected to the anode of the organic EL element 28. In addition, the cathode of the organic EL element 28 is connected to a grounding wire 5H that has ground potential. Note that the grounding wire 5H may be wired commonly for all pixels PXLC. In addition, the retention capacitor element 10C is disposed between the source and the gate of the driving transistor Tr2.

The sampling transistor Tr1 performs sampling on signal potential of a video signal supplied from the signal line DTL by being conductive according to a scanning signal (selection pulse) supplied from the scanning line WSL, and retains the signal potential in the retention capacitor element 10C. The driving transistor Tr2 receives supply of a current from the power supply line DSL set to have predetermined first electric potential (not illustrated), and then supplies a driving current to the organic EL element 28 according to the signal potential retained in the retention capacitor element 10C. The organic EL element 28 can emit light with luminance according to the signal potential of the video signal with the driving current supplied from the driving transistor Tr2. As the organic EL element 28 of each pixel PXLC is driven in this manner, video display based on the video signal is performed in the organic EL display device 1.

So far, the configuration example in which the TFT 10 according to the first embodiment is applied to a pixel driving element of the organic EL display device has been described. Here, as described in <1. First embodiment> above, the TFT 10 according to the first embodiment has high reliability in its operations because the carrier concentration distribution inside the oxide semiconductor layer 110 is controlled with high accuracy. Thus, by using the TFT 10 as the pixel driving element of the organic EL display device 1, higher reliability in the screen display function of the organic EL display device 1 can also be ensured.

### 5-2. Application to a Liquid Crystal Display Device

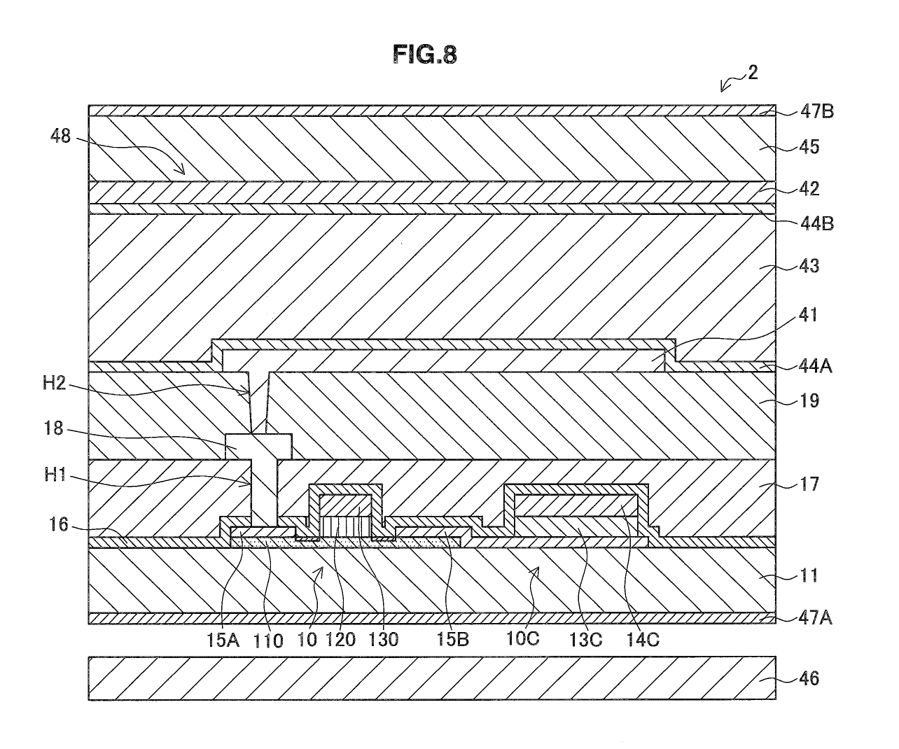

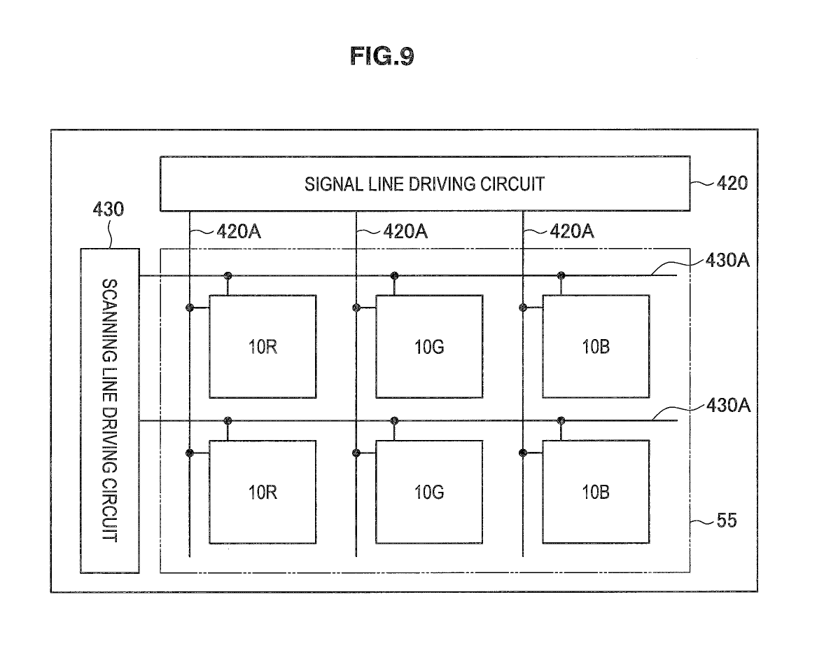

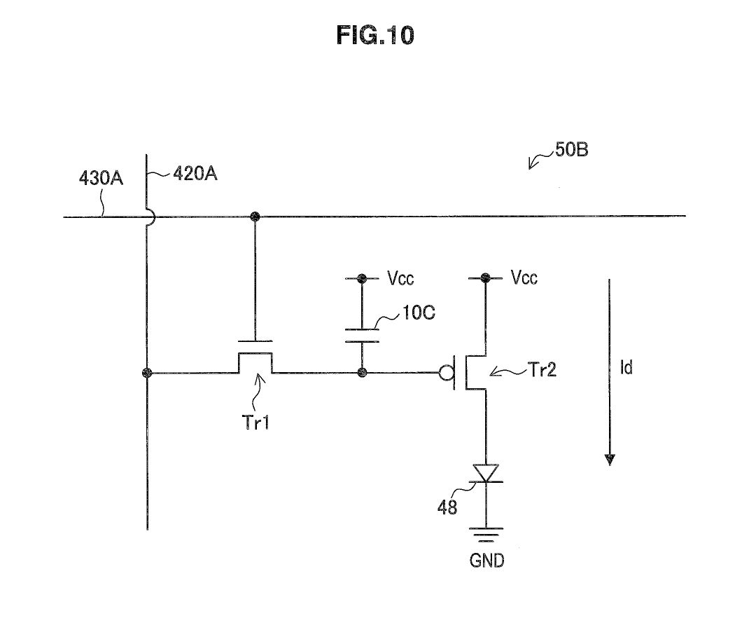

The TFT 10 according to the first embodiment can be suitably applied as a transistor for driving pixels in a liquid crystal display device. Here, the liquid crystal display device refers to a display device of which each pixel of a display screen are constituted by liquid crystal display elements, and which performs predetermined display on the display screen by selectively driving the liquid crystal display elements using a transistor that is a driving element. A configuration example in which the TFT 10 according to the first embodiment is applied to a pixel driving element of a liquid crystal display device will be described with reference to FIGS. 8 to 10. FIG. 8 is a cross-sectional diagram of a liquid crystal display device to which the TFT 10 according to the first embodiment is applied showing a schematic configuration of a region corresponding to one pixel. FIG. 9 is a schematic diagram of a circuit configuration of the liquid crystal display device to which the TFT 10 according to the first embodiment is applied. FIG. 10 is a schematic diagram showing a configuration of a periphery circuit of one pixel of the circuit configuration shown in FIG. 9 in detail.

Referring to FIG. 8, a liquid crystal display device 2 has the TFT 10 and the retention capacitor element 10C formed over the substrate 11. A liquid crystal display element 48 is provide in the upper layer of the TFT 10 and the retention capacitor element 10C having the flattening film 19 therebetween.

Here, the liquid crystal display device 2 shown in FIG. 8 corresponds to a configuration in which the organic EL element 28 of the organic EL display device 1 shown in FIG. 5 described above is replaced with the liquid crystal display element 48. Thus, the constituent elements other than the liquid crystal display element 48 in the configuration of the liquid crystal display device 2 shown in FIG. 8 may have the same functions as those already described with reference to FIG. 5. Thus, in description below with respect to the liquid crystal display device 2, differences from the organic EL display device 1 described above will be mainly described, and detailed description of overlapping matters will be omitted.

The liquid crystal display element 48 seals, for example, a liquid crystal layer 43 between a pixel electrode 41 and a counter electrode 42. In addition, an alignment film 44A is provided on the liquid crystal layer 43 side of the pixel electrode 41, and another alignment film 44B is provided on the liquid crystal layer 43 side of the counter electrode 42. The pixel electrode 41 is arranged for each pixel, and is electrically connected to, for example, the source or drain electrode 18 of the TFT 10. The counter electrode 42 is provided over a counter substrate 45 as a common electrode for a plurality of pixels, and retains, for example, predetermined common potential. The liquid crystal layer 43 includes liquid crystal driven in, for example, a vertical alignment (VA) mode, a twisted nematic (TN) mode, an in-plane switching (IPS) mode, or the like.

In addition, a backlight 46 is provided at the lower side of the substrate 11. A polarization plate 47A is affixed onto the surface of the substrate 11 on the backlight 46 side. In addition, another polarization plate 47B is affixed onto the top surface of the counter substrate 45.

The backlight 46 is a light source that radiates light toward the liquid crystal layer 43, and includes, for example, a plurality of light emitting diodes (LED), cold cathode fluorescent lamps (CCFL), and the like. The backlight 46 is driven by a backlight driving unit that is not illustrated, and controlled to be in an on state and an off state.

The polarization plates 47A and 47B are members which are also called polarizers or analyzers, and are arranged in, for example, a crossed-nicols state. Accordingly, the liquid crystal display device 2 is configured such that, for example, illuminating light from the backlight 46 is blocked in a no-voltage-applied state (off state) and is allowed to transmit through the device in a voltage-applied state (on state).

So far, the schematic configuration of the pixel region of the liquid crystal display device 2 in which the TFT 10 according to the first embodiment is mounted has been described. Next, a circuit configuration relating to driving of each pixel of the liquid crystal display device 2 will be described with reference to FIGS. 9 and 10.

As shown in FIGS. 9 and 10, the liquid crystal display device 2 has a plurality of pixels 10R, 10G, and 10B each of which includes the liquid crystal display element 48 described above. The pixels 10R, 10G, and 10B are arranged in, for example, a matrix shape in a display region 55 over the substrate 11. Each of the pixels 10R, 10G, and 10B is a pixel having the liquid crystal display element 48 that emits red (R) light, green (G) light, or blue (B) light. In the periphery of the display region 55, a signal line driving circuit 420 and a scanning line driving circuit 430 which are drivers for video display are provided.

FIG. 10 illustrates a specific circuit configuration example of any one of the pixels 10R, 10G, and 10B. Each of the pixels 10R, 10G, and 10B has a pixel circuit 50B that includes the organic EL element 28. In the example illustrated, the pixel circuit 50B is an active-type driving circuit that has a Tr1, a Tr2, the retention capacitor element 10C, and the liquid crystal display element 48. Note that at least one of the Tr1 and the Tr2 corresponds to the TFT 10 according to the first embodiment.

The retention capacitor element 10C is provided between the transistor Tr1 and the transistor Tr2, and the liquid crystal display element 48 is connected to the transistor Tr2 in series between a first power supply line (Vcc) and a second power supply line (GND). As shown in FIGS. 9 and 10, a plurality of signal lines 420A are arranged in the column direction, and a plurality of scanning lines 430A are arranged in the row direction in the pixel circuit 50B. Each signal line 420A is connected to the signal line driving circuit 420, and video signals are supplied to the source electrode of the transistor Tr1 from the signal line driving circuit 420 through the signal line 420A. Each scanning line 430A is connected to the scanning line driving circuit 430, and scanning signals are set to be sequentially supplied to the gate electrode of the transistor Tr1 from the scanning line driving circuit 430 through the scanning line 430A. The retention capacitor element 10C retains electric potential corresponding to the video signals according to conduction of the transistor Tr1 caused by the supply of the scanning signals.

Further, the drain electrode of the transistor Tr1 is connected to the gate electrode of the transistor Tr2. Accordingly, the transistor Tr2 becomes conductive according to the electric potential of the video signals retained in the retention capacitor element 10C, and a driving current Id is supplied to the liquid crystal display element 48. The liquid crystal display element 48 can emit light with luminance according to the electric potential of the video signals due to the driving current supplied from the transistor Tr2. In this manner, the liquid crystal display element 48 of each of the pixels 10R, 10G, and 10B is driven, and thereby video display based on the video signals is performed in the liquid crystal display device 2.

So far, the configuration example in which the TFT 10 according to the first embodiment is applied to a pixel driving element of the liquid crystal display device has been described. Here, as described in <1. First embodiment> above, the TFT 10 according to the first embodiment has high reliability in its operations because the carrier concentration distribution inside the oxide semiconductor layer 110 is controlled with high accuracy. Thus, by using the TFT 10 as the pixel driving element of the liquid crystal display device 2, higher reliability in the screen display function of the liquid crystal display device 2 can also be ensured.

Note that, instead of the pixel circuit 50B of the liquid crystal display device 2 according to the present modified example, a circuit in which the liquid crystal display element 48 is replaced with the organic EL element 28 of the pixel circuit 50A shown in FIG. 7 described above may be used. In addition, conversely, instead of the pixel circuit 50A of the organic EL display device 1 described above, a circuit in which the organic EL element 28 is replaced with the liquid crystal display element 48 of the pixel circuit 50B shown in FIG. 10 may be used. As described above, the pixel driving circuits of the organic EL display device 1 and the liquid crystal display device 2 may be configured such that the organic EL element 28 and the liquid crystal display element 48 emit light with luminance according to video signals given from outside, and the configuration may be arbitrary.

### 5-3. Application to an Image Sensor

Herein, the TFTs 10, 20, 30, and 40 according to the first, second, third, and fourth embodiments described above are so-called top-gate TFTs in which the gate electrode 130, the source region, and the drain region are formed in the upper portion of the oxide semiconductor layer 110, however, the first, second, third, and fourth embodiments are not limited thereto. The TFTs 10, 20, 30, and 40 according to the first, second, third, and fourth embodiments may be so-called bottom-gate TFTs in which the gate electrode 130 is formed in the lower portion of the oxide semiconductor layer 110 and the source region and the drain region are formed in the upper portion of the oxide semiconductor layer 110.

Herein, exemplifying a TFT 80 that has a bottom-gate configuration as a modified example of the first, second, third, and fourth embodiments, a case in which the TFT 80 is applied to a CMOS image sensor as a transistor for driving pixels will be described. The TFT 80 according to the modified example having the bottom-gate configuration can be suitably applied to an image sensor as a transistor for driving pixels. In the TFT 80 according to the present modified example, the carrier concentration distribution in which the carrier concentration increases from the source region and/or the drain region toward the channel region in stages inside the oxide semiconductor layer by using oxidation-reduction reactions between the first reduction reaction film 140, the second reduction reaction film 160 and/or the third reduction reaction film 180 with the oxide semiconductor layer can be formed even in a bottom-gate TFT, and performance of the TFT 80 can be improved.

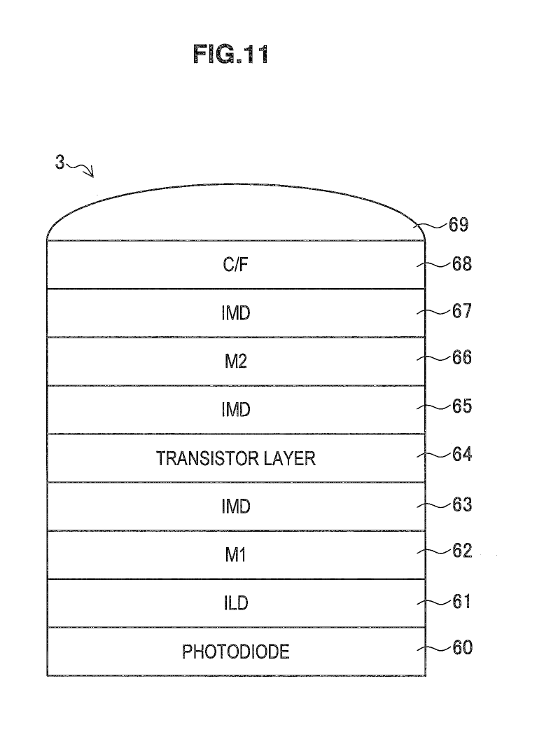

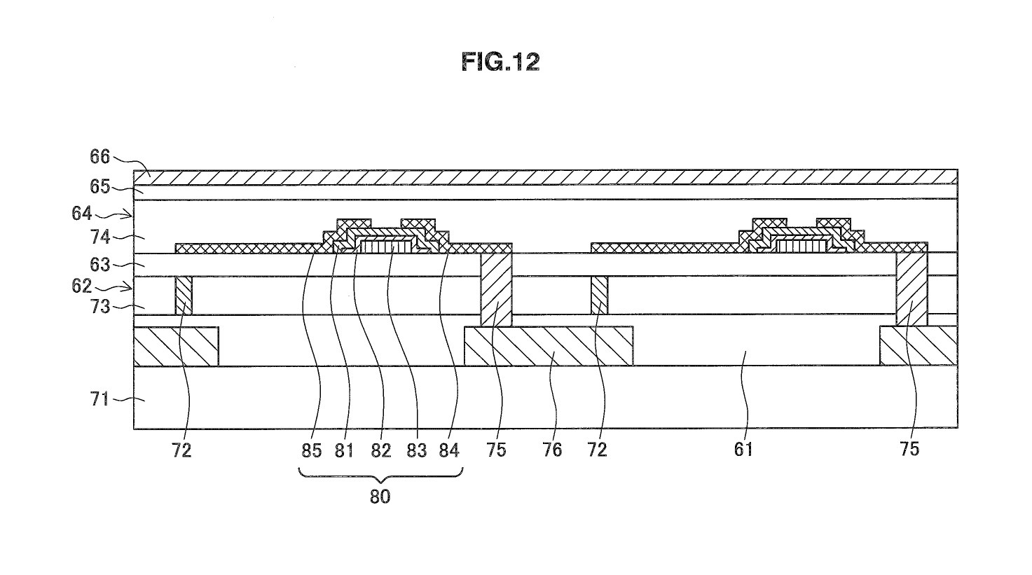

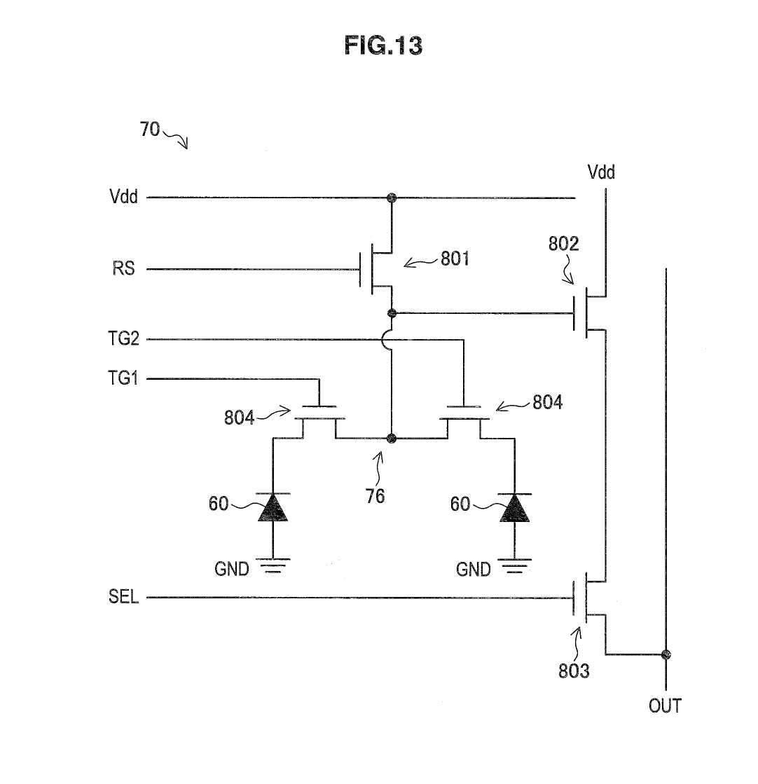

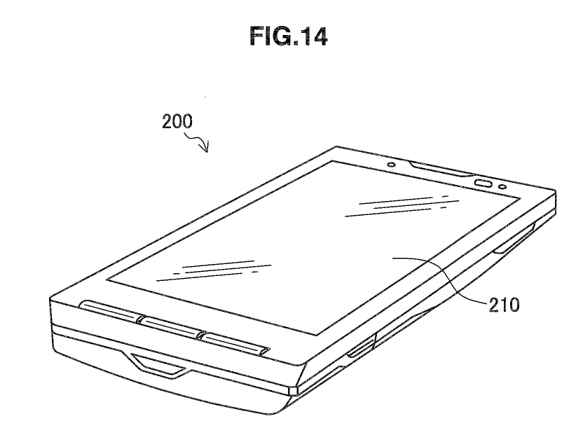

A configuration example in which the TFT 80 according to the modified example having the bottom-gate configuration which is a modified example of the first, second, third, and fourth embodiments is applied to a transistor for driving pixels in a CMOS image sensor will be described with reference to FIGS. 11 to 13. FIG. 11 is a schematic diagram showing a stacking structure of the CMOS image sensor to which the TFT 80 according to a modified example having a bottom-gate configuration is applied. FIG. 12 is a cross-sectional diagram of the CMOS image sensor to which the TFT according to the modified example is applied showing a schematic configuration of a region corresponding to one pixel. FIG. 13 is a schematic diagram showing a circuit configuration of the CMOS image sensor to which the TFT 80 according to the modified example is applied.

Referring to FIG. 11, in the CMOS image sensor 3 to which the TFT 80 according to the present modified example is applied, while a photodiode 60 that is a light receiving element in a pixel is formed in a diffusion layer, each transistor for driving the pixel is formed between a first wiring layer 62 (M1 layer 62) and a second wiring layer 66 (M2 layer 66). To be specific, on the photodiode 60 formed in the diffusion layer, a first insulation layer 61 that is an inter-layer dielectric (ILD), the first wiring layer 62, and a third insulation layer 63 that is a first inter-metal dielectric (IMD) are stacked in this order. In addition, in the upper layer of the third insulation layer 63, a transistor layer 64 in which respective transistors including the TFT 80 are formed is provided. Further, on the transistor layer 64, a fifth insulation layer 65 that is a second inter-metal dielectric (IMD), the second wiring layer 66, a seventh insulation layer 67 that is a third inter-metal dielectric (IMD), a color filter 68, and a micro-lens 69 are formed.

Referring to FIG. 12, the stacking structure of the CMOS image sensor 3 will be described in more detail. FIG. 12 is a cross-sectional diagram of a region corresponding to a pixel of the CMOS image sensor 3, showing a schematic configuration of a cross-section that includes one transistor included in the pixel.

Referring to FIG. 12, photodiodes (not illustrated) and floating diffusion regions 76 are formed on a substrate 71 in the CMOS image sensor 3. The substrate 71 is a semiconductor substrate composed of a semiconductor material, for example, silicon or the like. In addition, the photodiode and the floating diffusion regions 76 are formed as partial regions of the diffusion layer by performing an impurity injection step, for example, ion implantation, on the substrate 71 to form the diffusion layer. FIG. 12 is magnified such that the floating diffusion regions 76 appear to be formed in the upper layer of the substrate 71, however, the floating diffusion regions 76 and the photodiodes that are not illustrated may actually be formed in a region at a predetermined depth from the surface of the substrate 71.

The first insulation layer 61 that is an inter-layer dielectric (ILD) is provided in the upper layer of the substrate 71 so as to cover the floating diffusion regions 76 and the photodiodes. In addition, the first wiring layer 62 is formed on the first insulation layer 61. In the first wiring layer 62, wires 72 that are formed by processing a metal material in a predetermined pattern and a second insulation layer 73 for insulating the wires from each other are formed. The third insulation layer 63 that is the first inter-metal dielectric (IMD) is stacked on the first wiring layer 62, and the transistor layer 64 is further formed on the third insulation layer 63.

The first insulation layer 61, the second insulation layer 73 and the third insulation layer 63 may be formed of any of various insulation materials used for an inter-layer dielectric and inter-metal dielectric in general semiconductor processes. For example, the first insulation layer 61, the second insulation layer 73 and the third insulation layer 63 are formed of any of various insulation materials such as a silicon oxide, a silicon nitride, and a silicon oxy-nitride. In addition, the wires 72 may be formed of any of various conductive materials used as wires in general semiconductor processes. For example, the wires 72 are formed of any of various conductive materials such as aluminum or copper.

In the transistor layer 64, various transistors included in pixels of the CMOS image sensor 3 (for example, a transfer transistor, a reset transistor, an amplifying transistor, a selection transistor, and the like) are formed. In the present application example, the TFT 80 according to the present modified example is suitably applied to at least any of the transistors included in the pixels of the CMOS image sensor 3. FIG. 12 illustrates a schematic configuration of a cross-section of the TFT 80 that is one of the transistors in the channel direction. Note that functions of the transfer transistor, the reset transistor, the amplifying transistor, and the selection transistor in a pixel will be described later with reference to FIG. 13. In addition, with regard to the transfer transistor, the reset transistor, the amplifying transistor, and the selection transistor, stacking structures may be substantially the same although there are cases in which dimensions thereof, for example, gate lengths, gate widths, and the like are different from each other, and thus a stacking structure of the transistors will be described herein in brief with reference to the TFT 80 shown in FIG. 12.

Referring to FIG. 12, the TFT 80 has an oxide semiconductor layer 81, a gate insulation film 82, and a gate electrode 83. As described above, the TFT 80 is a TFT according to one modified example of the TFTs 10, 20, 30, and 40 according to the first, second, third, and fourth embodiments and has the bottom-gate configuration. As shown in FIG. 12, the gate electrode 83 and the gate insulation film 82 are stacked on the third insulation layer 63 in this order in the TFT 80. In addition, the gate electrode 83 is processed in a predetermined pattern. The oxide semiconductor layer 81 is stacked over the gate electrode 83 and the gate insulation film 82 in the TFT 80 so as to cover the gate insulation film 82. Here, the oxide semiconductor layer 81, the gate insulation film 82, and the gate electrode 83 are constituent members corresponding to the oxide semiconductor layer 110, the gate insulation film 120, and the gate electrode 130 of the TFTs 10, 20, 30, and 40, and can be formed of the same materials as the oxide semiconductor layer 110, the gate insulation film 120, and the gate electrode 130.

Although not illustrated in FIG. 12, regions having higher carrier concentrations than other regions which correspond to the first regions 111 and the second regions 112 due to reduction of the oxide semiconductor layer 81 by the first reduction reaction film 140 and the second reduction reaction film 160 are formed in the oxide semiconductor layer 81 as in the first, second, third, and fourth embodiments. For example, a carrier concentration distribution in which the carrier concentration increases from outside (i.e., a region that can be a source region or a drain region) toward the channel region immediately above the gate electrode 83 in stages is formed inside the oxide semiconductor layer 81. Note that, according to the third embodiment, a region corresponding to the third region 113 may be further formed in the oxide semiconductor layer 81 by further reducing the oxide semiconductor layer 81 using the third reduction reaction film 180.

A source wire 84 that can be a source electrode is formed on one side of an upper face of the oxide semiconductor layer 81 interleaved with the gate electrode 83. In addition, a drain wire 85 that can be a drain electrode is formed on the other side of the upper face of the oxide semiconductor layer 81 interleaved with the gate electrode 83. The source wire 84 and the drain wire 85 are processed in a predetermined pattern while being stretched in, for example, the horizontal direction in the transistor layer 64, and connected to a predetermined signal line. In the example shown in FIG. 12, for example, the source wire 84 is electrically connected to the floating diffusion region 76 through a plug 75 that is provided to penetrate the first insulation layer 61, the second insulation layer 73, and the third insulation layer 63. Note that the plug 75 can be formed by forming a through hole in the first insulation layer 61, the second insulation layer 73, and the third insulation layer 63 using, for example, the dry etching method, and embedding a conductive material such as tungsten in the through hole using a method such as a sputtering method.

In the transistor layer 64, a fourth insulation layer 74 is stacked on the TFT 80. Due to the fourth insulation layer 74, the source wire 84 and the drain wire 85 can be favorably insulated against each other. The fourth insulation layer 74 may be formed of the same insulating material as the first insulation layer 61, the second insulation layer 73, and the third insulation layer 63 described above.

So far, the configuration of the TFT 80 has been described in detail. The fifth insulation layer 65 which is the second inter-metal dielectric (IMD) and the second wiring layer 66 are stacked in this order on the transistor layer 64. Although not illustrated for simplification, wires on which various signals are applied to drive pixels are formed by processing a conductive material in a predetermined pattern. In addition, by embedding an insulating material between the wires in the second wiring layer 66, insulation between the wires is ensured. As the conductive material for forming the wires and the insulating material provided between the wires in the second wiring layer 66, for example, substantially the same materials as those of the wires 72 in the first wiring layer 62 and the second insulation layer 73 may be used.

Hereinabove, the schematic configuration of the pixel region of the CMOS image sensor 3 in which the TFT 80 according to the modified example having the bottom-gate configuration is mounted has been described. Next, a circuit configuration relating to driving of each pixel of the CMOS image sensor 3 will be described with reference to FIG. 13.

FIG. 13 is an equivalent circuit diagram showing a circuit configuration of a pixel circuit 70 of the CMOS image sensor 3. The pixel circuit 70 is constituted by the photodiodes 60, the floating diffusion region 76, a reset transistor 801, an amplifying transistor 802, a selection transistor 803, and transfer transistors 804. Note that at least one of the reset transistor 801, the amplifying transistor 802, the selection transistor 803, and the transfer transistors 804 corresponds to the TFT 80 described above.

As shown in FIG. 13, in the pixel circuit 70 of the CMOS image sensor 3, two photodiodes 60 are connected to one floating diffusion region 76 via the respective transfer transistors 804. In this manner, the pixel circuit 70 has the configuration in which the two photodiodes 60 share one floating diffusion region 76. The gate electrodes of the two transfer transistors 804 are connected to transfer lines TG1 and TG2, and by applying voltages to the transfer lines TG1 and TG2 at a predetermined timing, electric charge accumulated in the photodiodes 60 is transferred to the floating diffusion region 76 via the transfer transistors 804.

The floating diffusion region 76 is electrically connected to the source electrode of the reset transistor 801. The drain electrode of the reset transistor 801 is connected to a power supply line Vdd, retaining power supply potential. In addition, the gate electrode of the reset transistor 801 is connected to a reset line RG. By applying a voltage to the reset line RG at a predetermined timing, electric potential of the floating diffusion region 76 is retained as the same electric potential as that of the power supply line Vdd, and electric charge of the floating diffusion region 76 is reset.

In addition, the floating diffusion region 76 is electrically connected also to the gate electrode of the amplifying transistor 802. The drain electrode of the amplifying transistor 802 is connected to another power supply line Vdd, retaining power supply potential. In addition, the source electrode of the amplifying transistor 802 is connected to the drain electrode of the selection transistor 803. A constant current, for example, is applied between the source electrode and the drain electrode of the amplifying transistor 802, and thus the amplifying transistor 802 and the selection transistor 803 constitute a so-called source follower circuit. Since electric potential corresponding to the electric charge accumulated in the floating diffusion region 76 is applied to the gate electrode of the amplifying transistor 802, a current corresponding to the accumulated electric charge flows between the source electrode and the drain electrode of the amplifying transistor 802.

The gate electrode of the selection transistor 803 is connected to a selection line SEL, and by applying a voltage to the selection line SEL at a predetermined timing, the current flowing on the amplifying transistor 802 according to the electric charge accumulated in the floating diffusion region 76 is read out in the outside of the pixel circuit 70 (for example, a signal processing circuit provided in the later stage) via the selection transistor 803.

So far, the configuration example of the TFT 80 according to the modified example having the bottom-gate configuration in which it is applied to a transistor for driving pixels of the CMOS image sensor 3 serving as an image sensor has been described. Here, in the TFT 80 according to the present modified example, the carrier concentration distribution in which the carrier concentration increases from the source region and/or the drain region toward the channel region in stages inside the oxide semiconductor layer 81 by using oxidation-reduction reactions between the first reduction reaction film 140, the second reduction reaction film 160, and/or the third reduction reaction film 180 and the oxide semiconductor layer 81 can be formed as in the TFTs 10, 20, 30, and 40 according to the first, second, third, and fourth embodiments. Thus, as the carrier concentration distribution inside the oxide semiconductor layer 81 is controlled with high accuracy also in the TFT 80, higher reliability in operations thereof is ensured. Therefore, by using the TFT 80 as a transistor for driving the pixels of the CMOS image sensor 3, higher reliability in driving the pixels of the CMOS image sensor 3 can also be ensured.

Note that the circuit configuration of the pixel circuit 70 in which the above-described TFT 80 is mounted is not limited to the configuration shown in FIG. 13. The above-described TFT 80 and the TFTs 10, 20, 30, and 40 according to the first, second, third, and fourth embodiments can be applied to various known pixel circuits of general CMOS image sensors.

### 5-4. Application to Electronic Apparatuses Having Display Devices

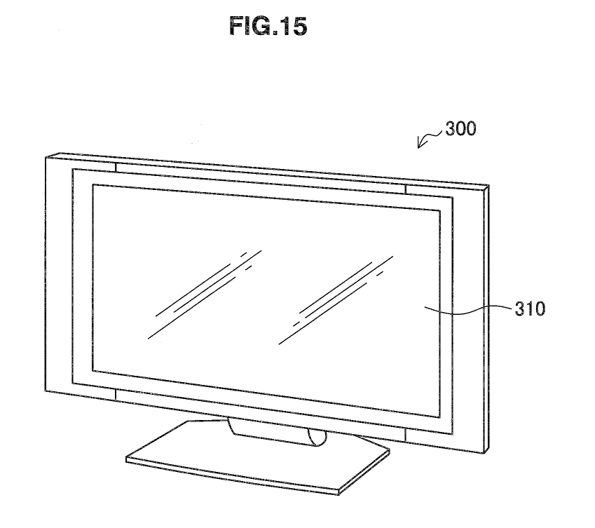

The organic EL display device 1, the liquid crystal display device 2, and the CMOS image sensor 3 in which any of the TFTs 10, 20, 30, 40, and 80 described above can be suitably applied to various kinds of electronic apparatuses as shown in, for example, FIGS. 14 to 16.

FIG. 14 is an external appearance diagram of a smartphone to which the organic EL display device 1, the liquid crystal display device 2 and/or the CMOS image sensor 3 are applied. Referring to FIG. 14, the smartphone 200 has a display screen 210 configured as, for example, a touch panel. On the display screen 210, various kinds of information processed by the smartphone 200 can be displayed in various forms of text, images, graphs, and the like, and a user can be notified thereof. In the smartphone 200, the above described organic EL display device 1 or the liquid crystal display device 2 is mounted, and the display screen 210 corresponds to the display region 50 of the organic EL display device 1 or the display region 55 of the liquid crystal display device 2. In addition, when the smartphone 200 has an imaging function, the CMOS image sensor 3 is mounted in the smartphone 200 as an image sensor to realize the imaging function.

FIG. 15 is an external appearance diagram of a display device 300 to which the organic EL display device 1 or the liquid crystal display device 2 is applied. Referring to FIG. 15, the display device 300 has a display screen 310. On the display screen 310, various kinds of information processed by the display device 300 can be displayed in various forms of text, images, graphs, and the like, and a user can be notified thereof. For example, the display device 300 can receive various kinds of content such as television programs, movies, dynamic images, and the like distributed by broadcasting stations and content distribution servers, and cause the content to be displayed on the display screen 310. In addition, the display device 300 may be connected to an information processing device such as a personal computer (PC), and various kinds of information processed by the information processing device may be displayed on the display screen 310 of the display device 300. In the display device 300, the above-described organic EL display device 1 or the liquid crystal display device 2 is mounted, and the display screen 310 corresponds to the display region 50 of the organic EL display device 1 or the display region 55 of the liquid crystal display device 2.

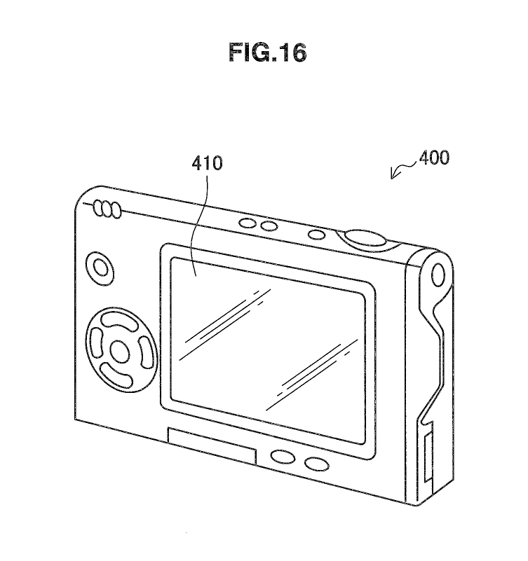

FIG. 16 is an external appearance diagram of an imaging device 400 to which the organic EL display device 1, the liquid crystal display device 2 and/or the CMOS image sensor 3 are applied. Referring to FIG. 16, the imaging device 400 has a display screen 410 in a region of a housing thereof. The imaging device 400 may be a so-called digital camera, for example, a digital still camera, a digital video camera, or the like that generates an image of a subject as digital data by receiving light from the subject and converts the light into an electrical signal using an image sensor. As the image sensor that converts light from a subject into an electrical signal, for example, the above-described CMOS image sensor 3 can be mounted in the imaging device 400. In addition, the above-described organic EL display device 1 or the liquid crystal display device 2 may be mounted in the imaging device 400, and the display screen 410 may correspond to display region 50 of the organic EL display device 1 or the display region 55 of the liquid crystal display device 2. On the display screen 410, various kinds of information processed by the imaging device 400 can be displayed in various forms of text, images, graphs, and the like, and a user can be notified thereof. For example, on the display screen 410, image information such as still images and dynamic images acquired by the imaging device 400, a setting screen for setting various photographing conditions at the time of imaging (for example, a shutter speed, an exposure value, and the like), and the like can be displayed.

So far, the examples of the electronic apparatuses to which the organic EL display device 1, the liquid crystal display device 2, and the CMOS image sensor 3 in which any of the TFTs 10, 20, 30, 40, and 80 is mounted can be applied have been described with reference to FIGS. 14 to 16. As described above, the organic EL display device 1 and the liquid crystal display device 2 in which any of the TFTs 10, 20, 30, 40, and 80 is mounted can be applied to various kinds of electronic apparatuses as display screens. By using the organic EL display device 1 and the liquid crystal display device 2 as display screens of electronic apparatuses, high reliability in pixel driving operations performed to display images on the display screens is secured, and a more stable image display function is realized.

In addition, as described above, the CMOS image sensor 3 in which any of the TFTs 10, 20, 30, 40, and 80 is mounted can be applied to various kinds of electronic apparatuses as an image sensor. By using the CMOS image sensor 3 as an image sensor of the electronic apparatuses, high reliability in pixel driving operations performed to acquire images captured by the image sensor is secured, and a more stable imaging function is realized.

Note that an electronic apparatus to which the organic EL display device 1, the liquid crystal display device 2, and the CMOS image sensor 3 in which any of the TFTs 10, 20, 30, 40, and 80 is mounted can be applied is not limited to the above examples, and the organic EL display device 1, the liquid crystal display device 2, and the CMOS image sensor 3 may be applied to any electronic apparatus as long as it has a display function and/or an imaging function.

### 6. Supplement

Although exemplary embodiments of the present disclosure have been described in detail above with reference to the accompanying drawings, the technical scope of the present disclosure is not limited thereto. It should be understood by those skilled in the art that various modifications, combinations, sub-combinations and alterations may occur depending on design requirements and other factors insofar as they are within the scope of the appended claims or the equivalents thereof.

Further, the effects described in the present specification are definitely illustrative and demonstrative, and not limitative. That is, the technology according to the present disclosure can exhibit other effects which are clear to those skilled in the art based on the description of the present specification, along with or instead of the above-described effects.

Additionally, the present technology may also be configured as below.

(1) A semiconductor device including:

a first region which is, in an oxide semiconductor layer, a region having a higher carrier concentration than a channel region immediately below a gate electrode formed over the oxide semiconductor layer and is formed at least in a partial region other than the channel region; and

a second region which is, in the oxide semiconductor layer, a region having a higher carrier concentration than the first region and is formed farther from the channel region than the first region,

wherein the first region is formed through a first reduction reaction by stacking a first reduction reaction film over the oxide semiconductor layer and reducing the oxide semiconductor layer by the first reduction reaction film, and

wherein the second region is formed through a second reduction reaction by stacking a second reduction reaction film over the oxide semiconductor layer and reducing the oxide semiconductor layer by the second reduction reaction film.

(2) The semiconductor device according to (1),

wherein the first region and the second region are formed on at least one side of the gate electrode in a channel direction, and

wherein, in the second region, an electrode for causing a predetermined region including at least the first region and the second region to function as a source region or a drain region is formed.

(3) The semiconductor device according to (1) or (2),

wherein the first region includes an edge of the oxide semiconductor layer, the edge abutting the gate electrode, and

wherein the channel region, the first region, and the second region are consecutively formed in the channel direction of the gate electrode.

(4) The semiconductor device according to (3), further including:

a sidewall insulation film formed along a side surface of the gate electrode with a predetermined thickness,

wherein the second region includes an edge of the oxide semiconductor layer, the edge abutting the sidewall insulation film.

(5) The semiconductor device according to (4),

wherein the first reduction reaction is performed in a state in which the first reduction reaction film is stacked over the oxide semiconductor layer over which the gate electrode has been formed, and

wherein the second reduction reaction is performed, after the first reduction reaction, in a state in which the second reduction reaction film is stacked over the oxide semiconductor layer over which the sidewall insulation film has been further formed.

(6) The semiconductor device according to (4),

wherein the first reduction reaction and the second reduction reaction are performed concurrently in a state in which the first reduction reaction film is stacked over the oxide semiconductor layer over which the gate electrode has been formed and the second reduction reaction film is stacked over the oxide semiconductor layer over which the sidewall insulation film has been further formed.

(7) The semiconductor device according to any one of (1) to (6), wherein the first reduction reaction film and the second reduction reaction film are formed of materials having different reduction properties with respect to the oxide semiconductor layer.
(8) The semiconductor device according to any one of (1) to (7), wherein the second reduction reaction film is formed of a material having a higher reduction property than the first reduction reaction film with respect to the oxide semiconductor layer.
(9) The semiconductor device according to any one of (1) to (8), wherein the carrier concentrations of the first region and the second region are decided at least based on a material and a thickness of each of the first reduction reaction film and the second reduction reaction film and a heating condition in each of the first reduction reaction and the second reduction reaction.
(10) The semiconductor device according to any one of (1) to (9), further including:

a third region which is, in the oxide semiconductor layer, a region having a higher carrier concentration than the second region and is formed farther from the gate electrode than the second region,

wherein the third region is formed through a third reduction reaction by stacking a third reduction reaction film over the oxide semiconductor layer and by reducing the oxide semiconductor layer by the third reduction reaction film.

(11) The semiconductor device according to (10),

wherein the first reduction reaction is performed in a state in which the first reduction reaction film is stacked over the oxide semiconductor layer over which the gate electrode has been formed,

wherein the second reduction reaction is performed, after the first reduction reaction, in a state in which the second reduction reaction film is stacked over the oxide semiconductor layer over which a first sidewall insulation film having a predetermined thickness has been further formed along a side surface of the gate electrode, and

wherein the third reduction reaction is performed, after the second reduction reaction, in a state in which the third reduction reaction film is stacked over the oxide semiconductor layer over which a second sidewall insulation film having a predetermined thickness has been further formed along a side surface of the first sidewall insulation film.

(12) The semiconductor device according to (10) or (11), wherein the third reduction reaction film is formed of a material having a higher reduction property than the second reduction reaction film with respect to the oxide semiconductor layer.
(13) The semiconductor device according to any one of (1) to (9),

wherein both of the first region and the second region are formed only on one side of the gate electrode in a channel direction, and

wherein, in the second region on the one side, an electrode for causing a predetermined region including at least the first region and the second region to function as a source region or a drain region is formed.

(14) A display device in which a thin film transistor is used as a pixel driving element, the transistor including:

a first region which is, in an oxide semiconductor layer, a region having a higher carrier concentration than a channel region immediately below a gate electrode formed over the oxide semiconductor layer and is formed at least in a partial region other than the channel region; and

a second region which is, in the oxide semiconductor layer, a region having a higher carrier concentration than the first region and is formed farther from the channel region than the first region,

wherein the first region is formed through a first reduction reaction by stacking a first reduction reaction film over the oxide semiconductor layer and reducing the oxide semiconductor layer by the first reduction reaction film, and

wherein the second region is formed through a second reduction reaction by stacking a second reduction reaction film over the oxide semiconductor layer and reducing the oxide semiconductor layer by the second reduction reaction film.

(15) A manufacturing method of a semiconductor device, the manufacturing method including:

stacking a first reduction reaction film over an oxide semiconductor layer, then performing a first reduction reaction to reduce the oxide semiconductor layer using the first reduction reaction film, and forming, in the oxide semiconductor layer, a first region having a higher carrier concentration than a channel region immediately below a gate electrode formed over the oxide semiconductor layer at least in a partial region other than the channel region, and

stacking a second reduction reaction film over the oxide semiconductor layer, then performing a second reduction reaction to reduce the oxide semiconductor layer using the second reduction reaction film, and forming, in the oxide semiconductor layer, a second region having a higher carrier concentration than the first region farther from the channel region than the first region.

1. A semiconductor device comprising:
a first region which is, in an oxide semiconductor layer, a region having a higher carrier concentration than a channel region immediately below a gate electrode formed over the oxide semiconductor layer and is formed at least in a partial region other than the channel region; and
a second region which is, in the oxide semiconductor layer, a region having a higher carrier concentration than the first region and is formed farther from the channel region than the first region,
wherein the first region is formed through a first reduction reaction by stacking a first reduction reaction film over the oxide semiconductor layer and reducing the oxide semiconductor layer by the first reduction reaction film, and
wherein the second region is formed through a second reduction reaction by stacking a second reduction reaction film over the oxide semiconductor layer and reducing the oxide semiconductor layer by the second reduction reaction film.

2. The semiconductor device according to claim 1,
wherein the first region and the second region are formed on at least one side of the gate electrode in a channel direction, and
wherein, in the second region, an electrode for causing a predetermined region including at least the first region and the second region to function as a source region or a drain region is formed.

3. The semiconductor device according to claim 2,
wherein the first region includes an edge of the oxide semiconductor layer, the edge abutting the gate electrode, and
wherein the channel region, the first region, and the second region are consecutively formed in the channel direction of the gate electrode.

4. The semiconductor device according to claim 3, further comprising:
a sidewall insulation film formed along a side surface of the gate electrode with a predetermined thickness,
wherein the second region includes an edge of the oxide semiconductor layer, the edge abutting the sidewall insulation film.

5. The semiconductor device according to claim 4,
wherein the first reduction reaction is performed in a state in which the first reduction reaction film is stacked over the oxide semiconductor layer over which the gate electrode has been formed, and
wherein the second reduction reaction is performed, after the first reduction reaction, in a state in which the second reduction reaction film is stacked over the oxide semiconductor layer over which the sidewall insulation film has been further formed.

6. The semiconductor device according to claim 4,
wherein the first reduction reaction and the second reduction reaction are performed concurrently in a state in which the first reduction reaction film is stacked over the oxide semiconductor layer over which the gate electrode has been formed and the second reduction reaction film is stacked over the oxide semiconductor layer over which the sidewall insulation film has been further formed.

7. The semiconductor device according to claim 1, wherein the first reduction reaction film and the second reduction reaction film are formed of materials having different reduction properties with respect to the oxide semiconductor layer.

8. The semiconductor device according to claim 1, wherein the second reduction reaction film is formed of a material having a higher reduction property than the first reduction reaction film with respect to the oxide semiconductor layer.

9. The semiconductor device according to claim 1, wherein the carrier concentrations of the first region and the second region are decided at least based on a material and a thickness of each of the first reduction reaction film and the second reduction reaction film and a heating condition in each of the first reduction reaction and the second reduction reaction.

10. The semiconductor device according to claim 1, further comprising:
a third region which is, in the oxide semiconductor layer, a region having a higher carrier concentration than the second region and is formed farther from the gate electrode than the second region,
wherein the third region is formed through a third reduction reaction by stacking a third reduction reaction film over the oxide semiconductor layer and by reducing the oxide semiconductor layer by the third reduction reaction film.

11. The semiconductor device according to claim 10,
wherein the first reduction reaction is performed in a state in which the first reduction reaction film is stacked over the oxide semiconductor layer over which the gate electrode has been formed,
wherein the second reduction reaction is performed, after the first reduction reaction, in a state in which the second reduction reaction film is stacked over the oxide semiconductor layer over which a first sidewall insulation film having a predetermined thickness has been further formed along a side surface of the gate electrode, and
wherein the third reduction reaction is performed, after the second reduction reaction, in a state in which the third reduction reaction film is stacked over the oxide semiconductor layer over which a second sidewall insulation film having a predetermined thickness has been further formed along a side surface of the first sidewall insulation film.

12. The semiconductor device according to claim 10, wherein the third reduction reaction film is formed of a material having a higher reduction property than the second reduction reaction film with respect to the oxide semiconductor layer.

13. The semiconductor device according to claim 1,
wherein both of the first region and the second region are formed only on one side of the gate electrode in a channel direction, and
wherein, in the second region on the one side, an electrode for causing a predetermined region including at least the first region and the second region to function as a source region or a drain region is formed.

14. A display device in which a thin film transistor is used as a pixel driving element, the transistor comprising:
a first region which is, in an oxide semiconductor layer, a region having a higher carrier concentration than a channel region immediately below a gate electrode formed over the oxide semiconductor layer and is formed at least in a partial region other than the channel region; and
a second region which is, in the oxide semiconductor layer, a region having a higher carrier concentration than the first region and is formed farther from the channel region than the first region,
wherein the first region is formed through a first reduction reaction by stacking a first reduction reaction film over the oxide semiconductor layer and reducing the oxide semiconductor layer by the first reduction reaction film, and
wherein the second region is formed through a second reduction reaction by stacking a second reduction reaction film over the oxide semiconductor layer and reducing the oxide semiconductor layer by the second reduction reaction film.

15. A manufacturing method of a semiconductor device, the manufacturing method comprising:
stacking a first reduction reaction film over an oxide semiconductor layer, then performing a first reduction reaction to reduce the oxide semiconductor layer using the first reduction reaction film, and forming, in the oxide semiconductor layer, a first region having a higher carrier concentration than a channel region immediately below a gate electrode formed over the oxide semiconductor layer at least in a partial region other than the channel region, and
stacking a second reduction reaction film over the oxide semiconductor layer, then performing a second reduction reaction to reduce the oxide semiconductor layer using the second reduction reaction film, and forming, in the oxide semiconductor layer, a second region having a higher carrier concentration than the first region farther from the channel region than the first region.
